(19) United States
(12) Patent Application Publication
(10) Pub. No.: US 2018/0190892 A1
(43) Pub. Date: Jul. 5, 2018

(54) THERMOELECTRIC CONVERSION MODULE, METHOD OF MANUFACTURING THERMOELECTRIC CONVERSION MODULE, AND THERMALLY CONDUCTIVE SUBSTRATE

(71) Applicant: FUJIFILM Corporation, Tokyo (JP)

(72) Inventors: Shinji IMAI, Ashigara-kami-gun (JP); Hideyuki SUZUKI, Ashigara-kami-gun (JP)

(73) Assignee: FUJIFILM Corporation, Tokyo (JP)

(21) Appl. No.: 15/906,796

(22) Filed: Feb. 27, 2018

Related U.S. Application Data
(63) Continuation of application No. PCT/JP2016/075217, filed on Aug. 29, 2016.

(30) Foreign Application Priority Data
Aug. 31, 2015 (JP) 2015-170978
Dec. 25, 2015 (JP) 2015-254537

(51) Int. Cl. H01L 35/32

(52) U.S. Cl. CPC H01L 35/32; H01L 35/325

(57) ABSTRACT

The present invention addresses the problem of providing a thermoelectric conversion module which can be manufactured by a so-called roll-to-roll process with high productivity, a method of manufacturing the thermoelectric conversion module, and a thermally conductive substrate used for a thermoelectric conversion module and the like. The thermoelectric conversion module includes a long insulating support having flexibility, a plurality of metal layers which are formed on one surface of the support with intervals in a longitudinal direction of the support, a plurality of thermoelectric conversion layers which are formed on the same surface of the support on which the metal layers are formed with intervals in the longitudinal direction of the support, and a connection electrode which connects the thermoelectric conversion layers adjacent to each other in the longitudinal direction of the support, in which the metal layer has low stiffness portions having stiffness lower than that of other regions in parallel with a width direction of the support, an interval between the low stiffness portions is constant, and further, the module is alternately bent in a mountain-folded manner and a valley-folded manner at the low stiffness portions of the metal layer in the longitudinal direction.

### CROSS-REFERENCE TO RELATED APPLICATIONS

This application is a Continuation of PCT International Application No. PCT/JP2016/075217 filed on Aug. 29, 2016, which claims priority under 35 U.S.C. § 119(a) to Japanese Patent Application No. 2015-170978 filed on Aug. 31, 2015 and Japanese Patent Application No. 2015-254537 filed on Dec. 25, 2015. Each of the above applications is hereby expressly incorporated by reference, in its entirety, into the present application.

### BACKGROUND OF THE INVENTION

### 1. Field of the Invention

The present invention relates to a thermoelectric conversion module having good productivity, a method of manufacturing the thermoelectric conversion module, and a thermally conductive substrate used for a thermoelectric conversion module or the like.

### 2. Description of the Related Art

Thermoelectric conversion materials capable of converting heat energy to electrical energy and vice versa are used in thermoelectric conversion elements such as power generation elements or Peltier elements which generate power using heat.

Thermoelectric conversion elements are capable of directly converting heat energy to electric power and, advantageously, do not require any movable portions. Therefore, thermoelectric conversion modules (power generation devices) obtained by connecting a plurality of thermoelectric conversion elements are capable of easily obtaining electric power without the need of operation costs by being provided in, for example, heat discharging portions of incineration furnaces, various facilities in plants, and the like.

As a thermoelectric conversion element, a so-called π-type thermoelectric conversion element using a thermoelectric conversion material such as Bi—Te is known.

A π-type thermoelectric conversion element has a configuration in which a pair of electrodes that are arranged apart from each other is provided, and an N-type thermoelectric conversion layer formed of an N-type thermoelectric conversion material is provided on one of the electrodes, while a P-type thermoelectric conversion layer formed of a P-type thermoelectric conversion material is provided on the other electrode, such that the thermoelectric conversion materials are similarly arranged apart from each other, with the top surfaces of the two thermoelectric conversion materials being connected to each other through the electrodes.

In addition, a plurality of thermoelectric conversion elements are arranged such that the N-type thermoelectric conversion layer and the P-type thermoelectric conversion layer are alternately arranged, and the electrodes in a portion underneath the thermoelectric conversion materials are connected to each other in series. Thus, a thermoelectric conversion module including a large number of thermoelectric conversion elements is formed.

The problem of a thermoelectric conversion module of the related art is that so much time and labor is required for manufacturing for connecting a large number of thermoelectric conversion layers to each other in series. In addition, an influence of thermal strain or a change in thermal strain due to a difference in thermal expansion coefficient is repeatedly generated and thus a fatigue phenomenon at the interface easily occurs.

As a method of solving such problems, there is proposed a thermoelectric conversion module obtained by using a support having flexibility such as a resin film.

This thermoelectric conversion module has a configuration in which a p-type thermoelectric conversion layer and an n-type thermoelectric conversion layer, which are long in a width direction of the support, are alternately arranged on a surface of a long support having flexibility and insulating properties in a longitudinal direction of the support, and further an electrode is formed on the surface of the support such that the respective thermoelectric conversion layers are connected to each other in series.

This thermoelectric conversion module is brought into contact with a heat source by, for example, bending a support or winding a support in a columnar shape, and then arranging a thermally conductive plate in an upper portion and a lower portion. In addition, a thermoelectric conversion module may be formed in such a manner that a film of a thermoelectric conversion material is formed on the support and the support is bent while the support is being sandwiched between heat insulating plates.

In such a thermoelectric conversion module, a structure in which a large number of thermoelectric conversion layers are connected to each other in series by an electrode on the surface of the support having flexibility can be formed by, for example, a film formation technique and a film patterning technique.

Therefore, much less time and labor is required for producing a large number of connection portions for connecting a large number of thermoelectric conversion layers to each other, compared to the above-described π-type thermoelectric conversion module. In addition, by utilizing the point that the support has flexibility, a shape of a relatively high degree of freedom can be formed by deforming the support itself even after the thermoelectric conversion layer, the electrode, and the like are formed.

Specifically, for example, FIG. 14 of JP2013-225550A shows a thermoelectric conversion module (thermoelectric conversion device) in which an n-type thermoelectric conversion layer and a p-type thermoelectric conversion layer are formed to be alternately arranged on a surface of a flexible support, front and rear surfaces of the flexible support are cut to sandwich a heat insulating sheet therebetween in each set of the n-type thermoelectric conversion layer and the p-type thermoelectric conversion layer, and the flexible support is folded in each set of the n-type thermoelectric conversion layer and the p-type thermoelectric conversion layer.

FIG. 5 of JP2012-174911A shows a bellows-like thermoelectric conversion module in which in strip-like n-type thermoelectric conversion layer and p-type thermoelectric conversion layer are alternately arranged, and end portions in a transverse direction are bonded using a conductive adhesive in a range of about 1 to 2 mm to fold each thermoelectric conversion layer although a support having flexibility is not used.

JP2004-104041A discloses a thermoelectric conversion module (thermoelectric conversion device) in which a plurality of kinds of long thermoelectric conversion layers are alternately arranged on one surface of a support, and end portions of the plurality of kinds of long thermoelectric conversion layers are connected to each other in a direction crossing the arrangement direction.

Further, JP2007-518252A discloses a thermoelectric conversion module (thermoelectric conversion device) including a thin p-type thermoelectric conversion layer formed on a surface of a flexible support by sputtering, a thin n-type thermoelectric conversion layer formed on the surface of the flexible support to be adjacent to the thin p-type thermoelectric conversion layer by sputtering, and a conductive member which electrically connects a first end portion of the thin p-type thermoelectric conversion layer formed on the surface of the flexible support and a second end portion of the thin n-type thermoelectric conversion layer. In FIG. 7 of JP2007-518252A, a bellows-like thermoelectric conversion module in which a narrow tape-shaped flexible support is used and the flexible substrate is folded in each combination of the thin n-type thermoelectric conversion layer and the thin p-type thermoelectric conversion layer is shown.

### SUMMARY OF THE INVENTION

However, in a folded thermoelectric conversion module using a flexible support of the related art a lot of improvements are required.

For example, in the thermoelectric conversion module disclosed in JP2013-225550A, it is difficult to cut the front and rear surfaces of the substrate. In addition, in a case where the rear surface of the substrate is not cut, there are concerns that the position of a fold in a case of folding back is not determined, the shape of the thermoelectric conversion module after folding is not determined, and the utilization efficiency of heat is lowered in a case of contact with a heat source.

In the thermoelectric conversion module disclosed in JP2012-174911A in which a flexible support is not used, since the p-type thermoelectric conversion layer and the n-type thermoelectric conversion layer are individual members before bonding, handling thereof is difficult due to the influence of static electricity and there is a concern of the manufacturing process being complicated.

In the thermoelectric conversion module disclosed JP2004-104041A, the thermoelectric conversion layers are bonded at the end portion in the longitudinal direction using a long thermoelectric conversion layer and thus there is a concern of increasing the height of the module, that is, a distance between the heat sources.

In the thermoelectric conversion module disclosed in JP2007-518252A, in the configuration in which a thermoelectric conversion layer is formed on a narrow tape-shaped flexible support, there are concerns that handleability is poor, the position of a fold in a case of folding back is not determined, the shape of the thermoelectric conversion layer after folding is not determined, and the utilization efficiency of heat is lowered in a case of contact with a heat source.

An object of the present invention is to solve such problems of related art and to provide a thermoelectric conversion module which can be manufactured by a so-called roll-to-roll process, can exhibit high productivity with a simple manufacturing process and good handleability by being wound in a roll shape, and can set an appropriate position of a fold in a case of folding back, a method of manufacturing the thermoelectric conversion module, and a thermally conductive substrate used for a thermoelectric conversion module or the like.

In order to achieve such an object, according to a first aspect of the present invention, there is provided a thermoelectric conversion module comprising:

a long insulating support having flexibility;

a plurality of metal layers which are formed on one surface of the support with intervals in a longitudinal direction of the support;

a plurality of thermoelectric conversion layers which are formed on the same surface of the support on which the metal layers are formed with intervals in the longitudinal direction of the support; and

a connection electrode which connects the thermoelectric conversion layers adjacent to each other in the longitudinal direction of the support,

in which the metal layer has low stiffness portions having stiffness lower than that of other regions in parallel with a width direction of the support, an interval between the low stiffness portions is constant in the longitudinal direction of the support, and further, the module is alternately bent in a mountain-folded manner and a valley-folded manner at the low stiffness portions of the metal layer in the longitudinal direction.

In the first aspect of the thermoelectric conversion module according to the present invention, it is preferable that the connection electrode functions as a metal layer.

It is preferable that the low stiffness portion is at least either one of one or more slits formed on the metal layer to be parallel with the width direction of the support or a broken line formed on the metal layer to be parallel with the width direction of the support.

It is preferable that a p-type thermoelectric conversion layer and an n-type thermoelectric conversion layer which are alternately formed in the longitudinal direction of the support as the thermoelectric conversion layers are provided.

According to a second aspect of the present invention, there is provided a thermoelectric conversion module comprising:

a module main body formed of the thermoelectric conversion module according to the first aspect; and

a thermally conductive substrate including a long insulating support having flexibility, and a plurality of metal layers entirely or partially formed on one surface of the support or formed with intervals in a longitudinal direction of the support, the metal layer having low stiffness portions having stiffness lower than that of other regions in parallel with a width direction of the support, the substrate being bent in a mountain-folded manner or a valley-folded manner, or alternately bent in a mountain-folded manner and a valley-folded manner at the low stiffness portions of the metal layer in the longitudinal direction,

in which the module main body and the thermally conductive substrate are laminated by directing the support of the thermally conductive substrate to a surface from which a connection electrode is exposed by bending of the module main body and fitting roughness of the module main body and roughness of the thermally conductive substrate to each other.

In the second aspect of the thermoelectric conversion module of the present invention, it is preferable that the thermally conductive substrate is laminated on both surfaces of the module main body by directing the support of the thermally conductive substrate to the module main body and fitting the roughness of the module main body and the roughness of the thermally conductive substrate to each other.

It is preferable that a distance between a top portion of a mountain fold portion of the thermally conductive substrate and a top portion of a mountain fold portion of the module main body is 0.5 to 5 times a height of the roughness of the module main body.

It is preferable that the thermally conductive substrate has roughness having different heights.

It is preferable that the thermally conductive substrate protrudes from the module main body in the width direction of the support.

It is preferable that the thermoelectric conversion module further comprises a heat dissipation member which is bent in a mountain-folded manner or a valley-folded manner, or alternately bent in a mountain-folded manner and a valley-folded manner and is formed of a long thermally conductive plate-like material, and the heat dissipation member is laminated on the thermally conductive substrate by fitting the roughness of the thermally conductive substrate and roughness the heat dissipation member to each other such that facing surfaces of top portions of mountain fold portions of the thermally conductive substrate and top portions of mountain fold portions of the heat dissipation member are separated from each other.

It is preferable that the heat dissipation member has low stiffness portions having stiffness lower than that of other regions in parallel with the width direction and is bent in a mountain-folded or a valley-folded manner, or alternately bent in a mountain-folded manner and a valley-folded manner at the low stiffness portions.

It is preferable that the heat dissipation member has roughness having different heights.

It is preferable that the thermoelectric conversion module further comprises a heat dissipation member which is bent in a mountain-folded manner or a valley-folded manner, or alternately bent in a mountain-folded manner and a valley-folded manner, is formed of a long thermally conductive plate-like material, and is larger than the module main body in the width direction, and the heat dissipation member is laminated on the thermally conductive substrate by fitting the roughness of the thermally conductive substrate and roughness of the heat dissipation member to each other such that the heat dissipation member protrudes from the module main body in the width direction of the support.

It is preferable that the heat dissipation member has low stiffness portions having stiffness lower than that of other regions in parallel with the width direction and is bent in a mountain-folded manner or a valley-folded manner, or alternately bent in a mountain-folded manner and a valley-folded manner at the low stiffness portions.

According to the present invention, there is provided a method of manufacturing a thermoelectric conversion module comprising:

performing, while transporting a long insulating support having flexibility in a longitudinal direction, a conversion layer forming step of forming a plurality of thermoelectric conversion layers on one surface of the support with intervals in the longitudinal direction of the support;

an electrode forming step of forming a connection electrode, which connects thermoelectric conversion layers adjacent to each other in the longitudinal direction of the support, on the same surface of the support on which the thermoelectric conversion layer is formed;

a metal layer forming step of forming a plurality of metal layers on the same surface of the support on which the thermoelectric conversion layer is formed with intervals in the longitudinal direction of the support; and

a low stiffness portion forming step of forming low stiffness portions having stiffness lower than that of other regions on the metal layer to be parallel with a width direction of the support so as to have a constant interval in the longitudinal direction of the support; and

further performing a bending step of after performing the metal layer forming step, the conversion layer forming step, the low stiffness portion forming step, and the electrode forming step, while transporting the support in the longitudinal direction, alternately bending the support in a mountain-folded manner and a valley-folded manner at the low stiffness portions of the metal layer in the longitudinal direction.

In the method of manufacturing a thermoelectric conversion module according to the present invention, it is preferable that the electrode forming step also functions as the metal layer forming step.

It is preferable that the support has a metal film formed on the entire one surface, and the electrode forming step, the metal layer forming step, and the low stiffness portion forming step are simultaneously performed by removing the metal film.

It is preferable that the bending step is performed by allowing the support to pass between gears having a pitch narrower than the interval between the low stiffness portions and engaged with each other.

According to the present invention, there is provided a thermally conductive substrate comprising:

a long insulating support having flexibility; and

a plurality of metal layers entirely or partially formed on one surface of the support, or formed with intervals in a longitudinal direction of the support,

in which the metal layer has low stiffness portions having stiffness lower than that of other regions in parallel with a width direction of the support, and further, the substrate is bent in a mountain-folded manner or a valley-folded manner, or alternately bent in a mountain-folded manner and a valley-folded manner at the low stiffness portions of the metal layer in the longitudinal direction.

According to a third aspect of the present invention, there is provided a thermoelectric conversion module comprising: a long insulating support having flexibility; and a plurality of thermoelectric conversion layers formed on one surface of the support with intervals in a longitudinal direction of the support, in which the thermoelectric conversion layer is electrically connected to an adjacent thermoelectric conversion layer in a side portion of the support in the longitudinal direction.

According to the present invention, it is possible to obtain a thermoelectric conversion module which can be manufactured by a roll-to-roll process, has a simple manufacturing process, exhibits high productivity and good handleability by being wound in a roll shape, and further can appropriately set the position of a fold in a case of folding, and a thermally conductive substrate used for a thermoelectric conversion module and the like.

### BRIEF DESCRIPTION OF THE DRAWINGS

FIG. 1A is a front view conceptually showing an example of a thermoelectric conversion module according to the present invention.

FIG. 1B is a plan view showing the thermoelectric conversion module shown in FIG. 1A in a partially enlarged manner.

FIG. 2A is a conceptual view for illustrating an example of a method of manufacturing a thermoelectric conversion module according to the present invention.

FIG. 2B is a conceptual view for illustrating the example of the method of manufacturing a thermoelectric conversion module according to the present invention.

FIG. 2C is a conceptual view for illustrating the example of the method of manufacturing the thermoelectric conversion module according to the present invention.

FIG. 3A is a conceptual view for illustrating the example of the method of manufacturing the thermoelectric conversion module according to the present invention.

FIG. 3B is a conceptual view for illustrating the example of the method of manufacturing the thermoelectric conversion module according to the present invention.

FIG. 4 is a conceptual view for illustrating the example of the method of manufacturing the thermoelectric conversion module according to the present invention.

FIG. 5A is a conceptual view for illustrating the example of the method of manufacturing the thermoelectric conversion module according to the present invention.

FIG. 5B is a conceptual view for illustrating the example of the method of manufacturing the thermoelectric conversion module according to the present invention.

FIG. 5C is a conceptual view for illustrating the example of the method of manufacturing the thermoelectric conversion module according to the present invention.

FIG. 6A is a front view conceptually showing an example of a thermally conductive substrate according to the present invention.

FIG. 6B is a front view conceptually showing an example of a thermally conductive substrate according to the present invention.

FIG. 6C is a front view conceptually showing an example of a thermally conductive substrate according to the present invention.

FIG. 6D is a front view conceptually showing an example of a thermally conductive substrate according to the present invention.

FIG. 7A is a conceptual view for illustrating an example of a method of manufacturing the thermally conductive substrates shown in FIGS. 6A to 6D.

FIG. 7B is a conceptual view for illustrating the example of the method of manufacturing the thermally conductive substrates shown in FIGS. 6A to 6D.

FIG. 7C is a conceptual view for illustrating the example of the method of manufacturing the thermally conductive substrates shown in FIGS. 6A to 6D.

FIG. 8 is a front view conceptually showing another example of the thermoelectric conversion module.

FIG. 9A is a conceptual view for illustrating an example of a method of manufacturing the thermoelectric conversion module shown in FIG. 8.

FIG. 9B is a conceptual view for illustrating the example of the method of manufacturing the thermoelectric conversion module shown in FIG. 8.

FIG. 9C is a conceptual view for illustrating the example of the method of manufacturing the thermoelectric conversion module shown in FIG. 8.

FIG. 10 is a view conceptually showing another example of the thermoelectric conversion module according to the present invention.

FIG. 11 is a view conceptually showing still another example of the thermoelectric conversion module according to the present invention.

FIG. 12 is a view conceptually showing still another example of the thermoelectric conversion module according to the present invention.

FIG. 13A is a view conceptually showing still another example of the thermoelectric conversion module according to the present invention.

FIG. 13B is a view conceptually showing still another example of the thermoelectric conversion module according to the present invention.

FIG. 14 is a view conceptually showing still another example of the thermoelectric conversion module according to the present invention.

FIG. 15 is a conceptual view for illustrating an example of usage of the thermoelectric conversion module shown in FIG. 14.

### DESCRIPTION OF THE PREFERRED EMBODIMENTS

Hereinafter, a thermoelectric conversion module, a method of manufacturing a thermoelectric conversion module, and a thermally conductive substrate according to the present invention will be described in detail based on preferable embodiments shown in the attached drawings.

In the specification, the numerical range indicated by using the expression “to” represents a range including numerical values indicated before and after the expression “to” respectively as the lower limit and the upper limit.

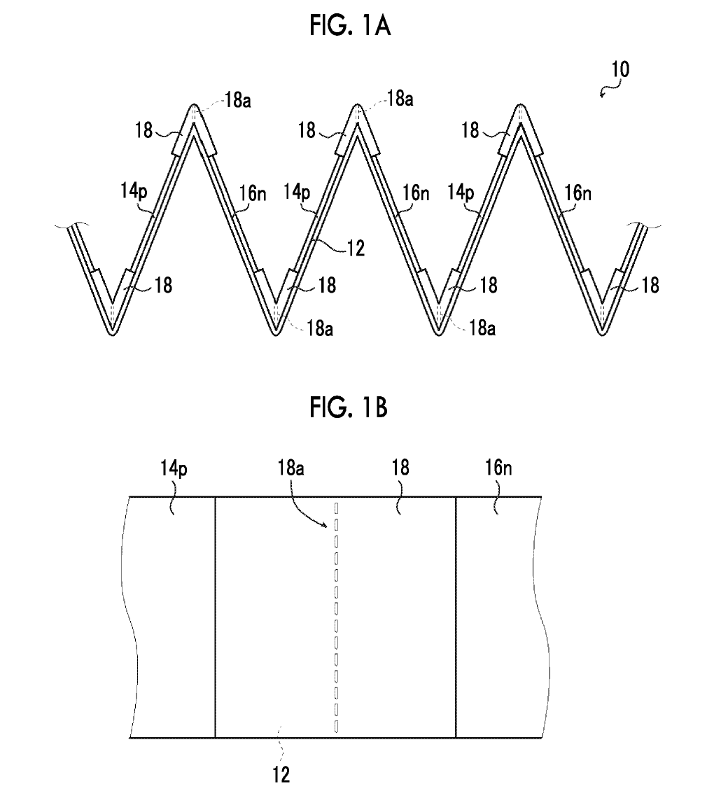

FIG. 1A shows a view conceptually showing an example of a thermoelectric conversion module according to the present invention. FIG. 1A is a front view and is a view as the thermoelectric conversion module of the present invention is seen from a plane direction of a support.

As shown in FIG. 1A, a thermoelectric conversion module 10 includes a support 12, a p-type thermoelectric conversion layer 14p, an n-type thermoelectric conversion layer 16n, and a connection electrode 18.

In the thermoelectric conversion module 10 shown in the example in the drawing, as a preferable embodiment, the connection electrode 18 functions as a metal layer in the present invention.

As shown in FIG. 1A, in the thermoelectric conversion module 10, the connection electrodes 18 having a fixed length are formed on one surface of the long support 12 at fixed intervals in a longitudinal direction of the support 12 and the p-type thermoelectric conversion layer 14p and the n-type thermoelectric conversion layer 16n having a fixed length are alternately formed on the same surface of the support 12 at fixed intervals in the longitudinal direction of the support 12.

In the present invention, the length in the longitudinal direction and the interval in the longitudinal direction are the length and the interval in a state in which the module 10 is extended in a planar shape.

In the following description, the “longitudinal direction of the support 12” is referred to as a “longitudinal direction”. As clearly seen from FIG. 1A, the longitudinal direction is a transverse direction in FIG. 1A. The width direction of the support 12 is a direction orthogonal to the longitudinal direction of the support 12.

In addition, in the following description, the “thermoelectric conversion module 10” is referred to as the “module 10”.

In addition, the module 10 is alternately bent at the connection electrodes 18 in a mountain-folded manner and a valley-folded manner by a broken line parallel with a width direction of the support 12 and is formed in a bellows-like shape. Accordingly, the module 10 alternately has a top portion (mountain portion) and a bottom portion (valley portion) in the longitudinal direction by bellows-like folding.

These broken lines, that is, low stiffness portions 18a of the connection electrodes 18 (metal layer) which will be described later are formed at fixed intervals in the longitudinal direction.

The module 10 has a configuration in which the above-described π-type thermoelectric conversion elements in which the p-type thermoelectric conversion layer 14p is connected to one of a pair of connection electrodes 18 separated from each other, the n-type thermoelectric conversion layer 16n is connected to the other, and the p-type thermoelectric conversion layer 14p and the n-type thermoelectric conversion layer 16n are connected at the end portion opposite to the separated connection electrodes 18 are connected to each other in series.

Accordingly, the module 10 generates powder by providing a high temperature heat source in the lower section in FIG. 1A and a low temperature heat source on the upper side (heat dissipation means such as a heat dissipating fin) and generating a temperature difference in a vertical direction in FIG. 1A. In other words, a temperature difference is generated in the thermoelectric conversion layer in the longitudinal direction to generate power.

The support 12 is long and has flexibility and also has insulating properties.

In the module of the present invention, for the support 12, various long sheet-like material (film) used in known thermoelectric conversion modules using a flexible support can be used as long as the material has flexibility and insulating properties.

Specific examples of the sheet-like material include sheet-like materials of polyester resins such as polyethylene terephthalate, polyethylene isophthalate, polyethylene naphthalate, polybutylene terephthalate, poly(1,4-cyclohexylene dimethylene terephthalate), and polyethylene-2,6-naphthalenedicarboxylate, resins such as polyimide, polycarbonate, polypropylene, polyethersulfone, cycloolefin polymer, and polyether ether ketone (PEEK), triacetyl cellulose (TAC), glass epoxy, and liquid crystal polyester.

Among these, from the viewpoint of thermal conductivity, heat resistance, solvent resistance, ease of availability, and economy, sheet-like materials of polyimide, polyethylene terephthalate, polyethylene naphthalate, and the like are suitably used.

Regarding the thickness of the support 12, the thickness at which sufficient flexibility is obtained and a function as the support 12 is provided can be appropriately set according to the material forming the support 12 or the like.

According to the study of the present inventors, the thickness of the support 12 is preferably 15 μm or less and more preferably 13 μm or less.

It is required for the module 10 of the present invention to maintain a state in which the module is alternately bent in a mountain-folded manner and a valley-folded manner. Although described later, in the module 10, by the plastic deformation of the connection electrode 18, that is, the metal layer, the bending is maintained. Here, in a case where the support 12 is thick, there is a possibility that the connection electrode 18 cannot maintain the bending of the support 12. In contrast, in a case where the thickness of the support 12 is set to 15 μm or less, the bending of the module 10 can be more suitably maintained by the connection electrode 18.

In addition, the thickness of the support 12 is preferably 15 μm or less from the viewpoint of being capable of improving the utilization efficiency of heat or the like.

The length and width of the support 12 may be appropriately set according to the size and the use of the module 10 or the like.

On one surface of the support 12, the p-type thermoelectric conversion layers 14p and the n-type thermoelectric conversion layers 16n having a fixed length are alternately arranged at fixed intervals in the longitudinal direction.

The configuration of the module 10 of the present invention is not limited to the configuration in which both the p-type thermoelectric conversion layer 14p and the n-type thermoelectric conversion layer 16n are provided. That is, the module 10 of the present invention may adopt a configuration in which only the p-type thermoelectric conversion layers 14p are arranged at intervals in the longitudinal direction or a configuration in which only the n-type thermoelectric conversion layers 16n are arranged at intervals in the longitudinal direction.

However, from the viewpoint of power generation efficiency or the like, as shown in the example of the drawing, it is preferable to provide both the p-type thermoelectric conversion layer 14p and the n-type thermoelectric conversion layer 16n.

In the following description, in a case where there is no need to distinguish the p-type thermoelectric conversion layer 14p and the n-type thermoelectric conversion layer 16n, the both layers are collectively referred to as the “thermoelectric conversion layer”.

In the module 10 of the present invention, for the p-type thermoelectric conversion layer 14p and the n-type thermoelectric conversion layer 16n, various thermoelectric conversion layers formed of known thermoelectric conversion materials can be used.

As the thermoelectric conversion material constituting the p-type thermoelectric conversion layer 14p and the n-type thermoelectric conversion layer 16n, for example, nickel or a nickel alloy may be used.

As the nickel alloy, various nickel alloys that generate power by causing a temperature difference can be used. Specific examples thereof include nickel alloys mixed with one or two or more of vanadium, chromium, silicon, aluminum, titanium, molybdenum, manganese, zinc, tin, copper, cobalt, iron, magnesium, and zirconium.

In a case where nickel or a nickel alloy is used for the p-type thermoelectric conversion layer 14p and/or the n-type thermoelectric conversion layer 16n, the nickel content in the p-type thermoelectric conversion layer 14p and the n-type thermoelectric conversion layer 16n is preferably 90% by atom or more and more preferably 95% by atom or more, and the thermoelectric conversion layers are particularly preferably formed of nickel. The p-type thermoelectric conversion layer 14p and the n-type thermoelectric conversion layer 16n formed of nickel include inevitable impurities.

In a case of using a nickel alloy as the thermoelectric conversion material for the p-type thermoelectric conversion layer 14p, chromel having nickel and chromium as main components is typically used. In a case of using a nickel alloy as the thermoelectric conversion material for the n-type thermoelectric conversion layer 16n, constantan having copper and nickel as main components is typically used.

In a case of using nickel or a nickel alloy for the p-type thermoelectric conversion layer 14p and/or the n-type thermoelectric conversion layer 16n, and in a case of using nickel or a nickel alloy for the connection electrode 18, the p-type thermoelectric conversion layer 14p, the n-type thermoelectric conversion layer 16n, and the connection electrode 18 may be integrally formed.

As other thermoelectric materials that can be used for the p-type thermoelectric conversion layer 14p and the n-type thermoelectric conversion layer 16n, the following materials in addition to nickel and nickel alloys may be used. Incidentally, the components in parentheses indicate the material composition.

Examples of the materials include BiTe-based materials (BiTe, SbTe, BiSe and compounds thereof), PbTe-based materials (PbTe, SnTe, AgSbTe, GeTe and compounds thereof), Si—Ge-based materials (Si, Ge, SiGe), silicide-based materials (FeSi, MnSi, CrSi), skutterudite-based materials (compounds represented by MX₃ or RM₄X₁₂, where M equals Co, Rh, or Ir, X equals As, P, or Sb, and R equals La, Yb, or Ce), transition metal oxides (NaCoO, CaCoO, ZnInO, SrTiO, BiSrCoO, PbSrCoO, CaBiCoO, BaBiCoO), zinc antimony based compounds (ZnSb), boron compounds (CeB, BaB, SrB, CaB, MgB, VB, NiB, CuB, LiB), cluster solids (B cluster, Si cluster, C cluster, AlRe, AlReSi), and zinc oxides (ZnO).

For the thermoelectric conversion material used for the p-type thermoelectric conversion layer 14p and the n-type thermoelectric conversion layer 16n, materials that can form a film by coating or printing and can be made into paste can be used.

Specific examples of the thermoelectric conversion material include an organic thermoelectric conversion material such as a conductive polymer or a conductive nanocarbon material may be used.

Examples of the conductive polymer include a polymer compound having a conjugated molecular structure (conjugated polymer). Specific examples thereof include known n-conjugated polymers such as polyaniline, polyphenylene vinylene, polypyrrole, polythiophene, polyfluorene, acetylene, and polyphenylene. Particularly, polydioxythiophene can be suitably used.

Specific examples of the conductive nanocarbon material include carbon nanotubes, carbon nanofiber, graphite, graphene, and carbon nanoparticles. These may be used singly or in combination of two or more thereof. Among these, from the viewpoint of further improving thermoelectric conversion properties, a carbon nanotube is preferably used. In the following description, the “carbon nanotube” is also referred to as “CNT”.

CNT is categorized into single layer CNT of one carbon film (graphene sheet) wound in the form of a cylinder, double layer CNT of two graphene sheets wound in the form of concentric circles, and multilayer CNT of a plurality of graphene sheets wound in the form of concentric circles. In the present invention, each of the single layer CNT, the double layer CNT, and the multilayer CNT may be used singly, or two or more thereof may be used in combination. Particularly, the single layer CNT and the double layer CNT excellent in conductivity and semiconductor characteristics are preferably used, and the single layer CNT is more preferably used.

The single layer CNT may be semiconductive or metallic. Furthermore, semiconductive CNT and metallic CNT may be used in combination. In a case where both of the semiconductive CNT and the metallic CNT are used, a content ratio between the CNTs can be appropriately adjusted. In addition, CNT may contain a metal or the like, and CNT containing fullerene molecules and the like may be used.

An average length of CNT is not particularly limited and can be appropriately selected. Specifically, from the viewpoint of ease of manufacturing, film formability, conductivity, and the like, the average length of CNT is preferably 0.01 to 2,000 μm, more preferably 0.1 to 1,000 μm, and particularly preferably 1 to 1,000 μm, though the average length also depends on an inter-electrode distance.

A diameter of CNT is not particularly limited. From the viewpoint of durability, transparency, film formability, conductivity, and the like, the diameter is preferably 0.4 to 100 nm, more preferably 50 nm or less, and particularly preferably 15 nm or less. Particularly, in a case where the single layer CNT is used, the diameter of CNT is preferably 0.5 to 2.2 nm, more preferably 1.0 to 2.2 nm, and particularly preferably 1.5 to 2.0 nm.

The CNT contains defective CNT in some cases. Because the defectiveness of the CNT deteriorates the conductivity of the thermoelectric conversion layer, it is preferable to reduce the amount of the defective CNT. The amount of defectiveness of the CNT can be estimated by a G/D ratio between a G band and a D band in a Raman spectrum. In a case where the G/D ratio is high, the composition can be assumed to be a CNT material with a small amount of defectiveness. The G/D ratio in the CNT is preferably 10 or higher and more preferably 30 or higher.

In the present invention, modified or treated CNT can also be used. Examples of the modification method and the treatment method include a method of incorporating a ferrocene derivative or nitrogen-substituted fullerene (azafullerene) into CNT, a method of doping CNT with an alkali metal (potassium or the like) or a metallic element (indium or the like) by an ion doping method, and a method of heating CNT in a vacuum.

In a case where CNT is used in the p-type thermoelectric conversion layer 14p and/or the n-type thermoelectric conversion layer 16n, in addition to the single layer CNT or the multilayer CNT, nanocarbons such as carbon nanohorns, carbon nanocoils, carbon nanobeads, graphite, graphene, amorphous carbon, and the like may be contained in the thermoelectric conversion layer.

In a case where CNT is used in the p-type thermoelectric conversion layer 14p and/or the n-type thermoelectric conversion layer 16n, it is preferable that the thermoelectric conversion layer includes a P-type dopant or an N-type dopant.

(p-Type Dopant)

Examples of the p-type dopant include halogen (iodine, bromine, or the like), Lewis acid (PFs, AsF₅, or the like), protonic acid (hydrochloric acid, sulfuric acid, or the like), transition metal halide (FeCl₃, SnCl₄, or the like), a metal oxide (molybdenum oxide, vanadium oxide, or the like), and an organic electron-accepting material. Examples of the organic electron-accepting material suitably include a tetracyanoquinodimethane (TCNQ) derivative such as 2,3,5,6-tetrafluoro-7,7,8,8-tetracyanoquinodimethane, 2,5-dimethyl-7,7,8,8-tetracyanoquinodimethane, 2-fluoro-7,7,8,8-tetracyanoquinodimethane, or 2,5-difluoro-7,7,8,8-tetracyanoquinodimethane, a benzoquinone derivative such as 2,3-dichloro-5,6-dicyano-p-benzoquinone or tetrafluoro-1,4-benzoquinone, 5,8H-5,8-bis(dicyanomethylene)quinoxaline, dipyrazino[2,3-f:2′,3′-h]quinoxaline-2,3,6,7,10,11-hexacarbonitrile, and the like.

Among these, from the viewpoint of the stability of the materials, the compatibility with CNT, and the like, organic electron-accepting materials such as a tetracyanoquinodimethane (TCNQ) derivative or a benzoquinone derivative are suitably exemplified.

The p-type dopant and the n-type dopant may be used singly or in combination of two or more thereof.

(n-Type Dopant)

As the n-type dopant, known materials such as (1) alkali metals such as sodium and potassium, (2) phosphines such as triphenylphosphine and ethylenebis(diphenylphosphine), (3) polymers such as polyvinyl pyrrolidone and polyethylene imine, and the like can be used.

In addition, for examples, polyethylene glycol type higher alcohol ethylene oxide adducts, ethylene oxide adducts of phenol, naphthol or the like, fatty acid ethylene oxide adducts, polyhydric alcohol fatty acid ester ethylene oxide adducts, higher alkylamine ethylene oxide adducts, fatty acid amide ethylene oxide adducts, ethylene oxide adducts of fat, polypropylene glycol ethylene oxide adducts, dimethylsiloxane-ethylene oxide block copolymers, dimethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Further, acetylene glycol-based and acetylene alcohol-based oxyethylene adducts, fluorine-based and silicon-based surfactants, and the like can be also used.

As the p-type thermoelectric conversion layer 14p and the n-type thermoelectric conversion layer 16n, the thermoelectric conversion layer obtained by dispersing the aforementioned thermoelectric conversion material in a resin material (binder) is suitably used.

Among these, the thermoelectric conversion layer obtained by dispersing a conductive nanocarbon material in a resin material is more suitably exemplified. Especially, the thermoelectric conversion layer obtained by dispersing CNT in a resin material is particularly suitably exemplified because this makes it possible to obtain high conductivity and the like.

As the resin material, various known nonconductive resin materials (polymer materials) can be used.

Specifically, it is possible to use a vinyl compound, a (meth)acrylate compound, a carbonate compound, an ester compound, an epoxy compound, a siloxane compound, and gelatin.

More specifically, examples of the vinyl compound include polystyrene, polyvinyl naphthalene, polyvinyl acetate, polyvinyl phenol, and polyvinyl butyral. Examples of the (meth)acrylate compound include polymethyl (meth)acrylate, polyethyl (meth)acrylate, polyphenoxy(poly)ethylene glycol (meth)acrylate, and polybenzyl (meth)acrylate. Examples of the carbonate compound include bisphenol Z-type polycarbonate, and bisphenol C-type polycarbonate. Examples of the ester compound include amorphous polyester.

Polystyrene, polyvinyl butyral, a (meth)acrylate compound, a carbonate compound, and an ester compound are preferable, and polyvinyl butyral, polyphenoxy(poly)ethylene glycol (meth)acrylate, polybenzyl (meth)acrylate, and amorphous polyester are more preferable.

In the thermoelectric conversion layer obtained by dispersing a thermoelectric conversion material in a resin material, a quantitative ratio between the resin material and the thermoelectric conversion material may be appropriately set according to the material used, the thermoelectric conversion efficiency required, the viscosity or solid content concentration of a solution exerting an influence on printing, and the like.

In a case where CNT is used in the p-type thermoelectric conversion layer 14p and/or the n-type thermoelectric conversion layer 16n, a thermoelectric conversion layer mainly constituted of CNT and a surfactant is also suitably used.

By constituting the thermoelectric conversion layer of CNT and a surfactant, the thermoelectric conversion layer can be formed using a coating composition to which a surfactant is added. Therefore, the thermoelectric conversion layer can be formed using a coating composition in which CNT is smoothly dispersed. As a result, by a thermoelectric conversion layer including a large amount of long and less defective CNT, excellent thermoelectric conversion performance is obtained.

As the surfactant, known surfactants can be used as long as the surfactants function to disperse CNT. More specifically, various surfactants can be used as the surfactant as long as surfactants dissolve in water, a polar solvent, or a mixture of water and a polar solvent and have a group adsorbing CNT.

Accordingly, the surfactant may be ionic or nonionic. Furthermore, the ionic surfactant may be any of cationic, anionic, and amphoteric surfactants.

Examples of the anionic surfactant include an aromatic sulfonic acid-based surfactant such as alkylbenzene sulfonate like dodecylbenzene sulfonate or dodecylphenylether sulfonate, a monosoap-based anionic surfactant, an ether sulfate-based surfactant, a phosphate-based surfactant and a carboxylic acid-based surfactant such as sodium deoxycholate or sodium cholate, and a water-soluble polymer such as carboxymethyl cellulose and a salt thereof (sodium salt, ammonium salt, or the like), a polystyrene sulfonate ammonium salt, or a polystyrene sulfonate sodium salt.

Examples of the cationic surfactant include an alkylamine salt and a quaternary ammonium salt. Examples of the amphoteric surfactant include an alkyl betaine-based surfactant, and an amine oxide-based surfactant.

Further, examples of the nonionic surfactant include a sugar ester-based surfactant such as sorbitan fatty acid ester, a fatty acid ester-based surfactant such as polyoxyethylene resin acid ester, and an ether-based surfactant such as polyoxyethylene alkyl ether.

Among these, an ionic surfactant is preferably used, and cholate or deoxycholate is particularly suitably used.

In the thermoelectric conversion layer having CNT and the surfactant, a mass ratio of surfactant/CNT is preferably 5 or less, and more preferably 3 or less.

It is preferable that the mass ratio of surfactant/CNT is 5 or less from the viewpoint that a higher thermoelectric conversion performance or the like is obtained.

If necessary, the thermoelectric conversion layer formed of an organic material may contain an inorganic material such as SiO₂, TiO₂, Al₂O₃, or ZrO₂.

In a case where the thermoelectric conversion layer contains an inorganic material, a content of the inorganic material is preferably 20% by mass or less, and more preferably 10% by mass or less.

The p-type thermoelectric conversion layer 14p and the n-type thermoelectric conversion layer 16n may be formed by a known method. For example, the following method is exemplified.

First, a coating composition for forming a thermoelectric conversion layer containing a thermoelectric conversion material and a required component such as a surfactant is prepared.

Next, the prepared coating composition which becomes the thermoelectric conversion layer is patterned and applied according to a thermoelectric conversion layer to be formed. The application of the coating composition may be performed by a known method such as a method using a mask or a printing method.

After the coating composition is applied, the coating composition is dried by a method according to the resin material, thereby forming the thermoelectric conversion layer. If necessary, after the coating composition is dried, the coating composition (resin material) may be cured by being irradiated with ultraviolet rays or the like.

Alternatively, the prepared coating composition which becomes the thermoelectric conversion layer is applied to the entire surface of the insulating substrate and dried, and then the thermoelectric conversion layer may be formed as a pattern by etching or the like.

In a case where the thermoelectric conversion layer mainly including CNT and a surfactant is formed, it is preferable to form the thermoelectric conversion layer by forming the thermoelectric conversion layer by the coating composition, then immersing the thermoelectric conversion layer in a solvent for dissolving the surfactant or washing the thermoelectric conversion layer with a solvent for dissolving the surfactant, and drying the thermoelectric conversion layer.

Thus, it is possible to form the thermoelectric conversion layer having a very small mass ratio of surfactant/CNT by removing the surfactant from the thermoelectric conversion layer and more preferably not containing the surfactant.

The thermoelectric conversion layer is preferably formed as a pattern by printing.

As the printing method, various known printing methods such as screen printing and metal mask printing can be used. In a case where the thermoelectric conversion layer is formed as a pattern by using a coating composition containing CNT, it is more preferable to use metal mask printing.

The printing conditions may be appropriately set according to the physical properties (solid content concentration, viscosity, and viscoelastic properties) of the coating composition used, the opening size of a printing plate, the number of openings, the opening shape, a printing area, and the like.

In a case where the p-type thermoelectric conversion layer 14p and the n-type thermoelectric conversion layer 16n are formed using the above-described inorganic material such as nickel, a nickel alloy, and a BiTe-based material, in addition to the formation method using such a coating composition, a film formation method such as a sputtering method, a vapor deposition method, a chemical vapor deposition (CVD) method, a plating method, or an aerosol deposition method can be used to form the thermoelectric conversion layer.

The size of the p-type thermoelectric conversion layer 14p and the n-type thermoelectric conversion layer 16n may be appropriately set according to the size of the module 10, the width of the support 12, the size of the connection electrode 18, and the like. In the present invention, the size refers to the size of the support 12 in the plane direction.

As described above, the p-type thermoelectric conversion layer 14p and the n-type thermoelectric conversion layer 16n have the same length in the longitudinal direction. In addition, since the thermoelectric conversion layers are formed at fixed intervals, the p-type thermoelectric conversion layer 14p and the n-type thermoelectric conversion layer 16n are alternately formed at equal intervals.

The thickness of the p-type thermoelectric conversion layer 14p and the n-type thermoelectric conversion layer 16n may be appropriately set according to the material forming the thermoelectric conversion layer and is preferably 1 to 20 μm and more preferably 3 to 15 μm.

It is preferable to set the thickness of the p-type thermoelectric conversion layer 14p and the n-type thermoelectric conversion layer 16n to be in the above range from the viewpoint of obtaining good electrical conductivity and obtaining good printing suitability.

The thickness of the p-type thermoelectric conversion layer 14p and the thickness of the n-type thermoelectric conversion layer 16n may the same or different from each other but basically the same.

In addition, the thickness of the p-type thermoelectric conversion layer 14p and the n-type thermoelectric conversion layer 16n is preferably smaller than the thickness of the connection electrode 18 which functions as a metal layer. In a case where a metal layer is provided separately from the connection electrode, the thickness of the p-type thermoelectric conversion layer 14p and the n-type thermoelectric conversion layer 16n is preferably smaller than the thickness of the metal layer.

By adopting such a configuration, in a case of compressing the bellows-like module 10, which will be described later, in the longitudinal direction, contact of the p-type thermoelectric conversion layer 14p and the n-type thermoelectric conversion layer 16n is not easily made.

In the module 10, the connection electrode 18 is formed on the surface of the support 12 on which the p-type thermoelectric conversion layer 14p and the n-type thermoelectric conversion layer 16n are formed.

The connection electrode 18 electrically connects the p-type thermoelectric conversion layer 14p and the n-type thermoelectric conversion layer 16n which are alternately formed in the longitudinal direction in series. As described above, in the example shown in the drawing, the thermoelectric conversion layers having a fixed length are formed at fixed intervals in the longitudinal direction. Accordingly, the connection electrodes 18 having a fixed length are formed at fixed intervals.

In the module 10 of the present invention, as long as the interval between the low stiffness portions 18a to be formed on the connection electrodes 18 (metal layers) which will be described later is a fixed interval in the longitudinal direction, the length and the intervals of the p-type thermoelectric conversion layers 14p, the n-type thermoelectric conversion layers 16n, and the connection electrodes 18 in the longitudinal direction are not necessarily constant. In a case where the connection electrode is provided separately from the metal layer, the same is applied to the length and the interval between the metal layers in the longitudinal direction.

In addition, in the module 10, the length, the formed interval, and the like between the thermoelectric conversion layers and between the connection electrodes 18 may be different in some cases.

Regarding the material forming the connection electrode 18, various conductive materials can be used as long as the material has a required conductivity.

Specific examples thereof include metal materials such as copper, silver, gold, platinum, nickel, aluminum, constantan, chromium, indium, iron, and copper alloys, and materials used for transparent electrodes in various devices, such as indium tin oxide (ITO) and zinc oxide (ZnO). Among these, copper, gold, silver, platinum, nickel, copper alloys, aluminum, constantan and the like are preferably exemplified and copper, gold, silver, platinum, and nickel are more preferably exemplified.

In addition, for example, the connection electrode 18 may be a laminated electrode having a configuration in which a copper layer is formed on a chromium layer or the like.

In a case where the connection electrode is provided separately from the metal layer, as the material forming the metal layer, all known metal materials can be used and the above-described metal materials are suitably exemplified.

As described above, in the module 10 of the present invention, the connection electrode 18 functions as a metal layer. Accordingly, the low stiffness portion 18a parallel with the width direction is formed in the connection electrode 18.

The low stiffness portions 18a are formed at fixed intervals in the longitudinal direction.

The low stiffness portion 18a is a portion having stiffness lower than that of other portions in the connection electrode 18, that is, a portion that is more easily bent than other portions.

FIG. 1B is a plan view conceptually showing the module 10 in a partially enlarged manner. The plan view of FIG. 1B is a view as the module 10 is seen from a direction orthogonal to the surface (maximum surface) of the support 12 and is a view as the module 10 is seen from the upper side of the drawing of FIG. 1A.

In the module 10 of the example in the drawing, a broken line parallel with the width direction is formed by the connection electrode 18 and thus the low stiffness portion 18a parallel with the width direction is formed. In other words, a portion with an electrode (metal) and a portion without an electrode (metal) are alternately formed in the width direction in the connection electrode 18 to form the low stiffness portion 18a.

Although described later, regarding the module 10 of the present invention, the connection electrode 18 having the low stiffness portion 18a, the p-type thermoelectric conversion layer 14p, and the n-type thermoelectric conversion layer 16n are formed on the plate-like support 12 and then the module is alternately bent in a mountain-folded manner and a valley-folded manner at each connection electrode 18 to form the bellows-like bent module 10 of the present invention as shown in FIG. 1A.

The bending is performed by bending the connection electrode 18 in the longitudinal direction. Accordingly, by providing the low stiffness portion 18a having stiffness lower than that of other regions in parallel with the width direction, the connection electrode 18 can be selectively bent at the low stiffness portion 18a. In addition, since the formation intervals of the low stiffness portions 18a are equal in the longitudinal direction, the positions of the top portions of the mountain fold portions and the bottom portions of the valley fold portions of all the connection electrodes 18 can be aligned.

As described above, the module 10 of the present invention generates power by generating a temperature difference in the vertical direction in FIG. 1A, that is, between the mountain fold portion (top portion, mountain portion) and the valley fold portion (bottom portion, valley portion) bent in a bellows-like shape. Accordingly, by aligning the positions of the top portions of all the mountain fold portions and the bottom portions of all the valley fold portions, the connection electrodes 18 on the high temperature side and the low temperature side can be effectively brought into contact with the high temperature heat source and the low temperature heat source, and thus power generation with high efficiency can be performed by improving the utilization efficiency of heat.

Further, although described later, in the manufacturing of the module 10 of the present invention, all of the formation of the connection electrode 18 having the low stiffness portion 18a, the formation of the thermoelectric conversion layer, bending processing and the like can be performed by a so-called roll-to-roll process. Accordingly, the module 10 is a thermoelectric conversion module that can be manufactured with high productivity and good handleability.

Accordingly, the interval between the low stiffness portions 18a in the longitudinal direction may be appropriately set according to the height required for the bellows-like folded module 10 or the like. In contrast, in a case where the height of the module 10 is limited, the interval between the low stiffness portions 18a in the longitudinal direction may be set according to the height limitation, and the size of the connection electrode 18, the p-type thermoelectric conversion layer 14p, and the n-type thermoelectric conversion layer 16n in the longitudinal direction may be set according to the interval between the low stiffness portions 18a.

The height of the module 10 refers to the size of the module 10 in the vertical direction in the drawing of FIG. 1A, that is, the size of the module in the arrangement direction of the high temperature heat source and the low temperature heat source.

In the module 10 of the present invention, the low stiffness portion is not limited to the broken line formed by the connection electrode 18 as shown in the example of the drawing, and as long as the portion has lower stiffness compared to other regions and in a case where the planar connection electrode 18 is bent in the longitudinal direction, the bent portion in the connection electrode 18 is selectively bent, various configurations can be used.

Examples thereof include a low stiffness portion in which one slit or a plurality of slits long in the width direction are formed to be arranged in the width direction and a low stiffness portion in which a thin portion having a smaller thickness than other regions is formed in a groove shape parallel with the width direction.

The low stiffness portion may be formed by a plurality of stiffness lowering methods such as adopting a configuration in which the vicinity of the end portion in the width direction has a broken line formed by the connection electrode 18 and the center portion in the width direction has a slit formed in the connection electrode 18, and the like.

Here, it is required to form the low stiffness portion 18a such that the connection electrode 18 (metal layer) is present in a region which becomes the low stiffness portion 18a. That is, it is required to form the low stiffness portion 18a such that in a case where the connection electrode 18 is seen from the longitudinal direction, the connection electrode 18 is provided in at least a part of the region in the width direction and in the entire region in the longitudinal direction.

In a case where a region in which the connection electrode 18 is not present is formed so as to penetrate the support in the width direction, there is a possibility that the support 12 may return its original planar shape by the elasticity and stiffness of the support 12 after the support 12 is bent.

In contrast, by providing a state in which the connection electrode 18 remains in the low stiffness portion 18a such as the broken line shape as shown in the example of the drawing, even after the support 12 is bent, the bent state of the support 12 can be maintained due to the plastic deformation of the connection electrode 18. In addition, as in the module 10 in the example of the drawing, even in a case where the metal layer functions as the connection electrode 18, the metal layer can electrically connect the thermoelectric conversion layers to each other.

Regarding the amount of the connection electrode 18 remaining in the low stiffness portion 18a, the amount in which a state in which the support 12 is bent can be maintained through the composition modification of the connection electrode 18 may be appropriately set according to the thickness or the stiffness of the connection electrode 18 and the like.

The size of the connection electrode 18 may be appropriately set according to the size of the module 10, the width of the support 12, the size of the p-type thermoelectric conversion layer 14p and the n-type thermoelectric conversion layer 16n, and the like.

Regarding the thickness of the connection electrode 18, the thickness at which sufficient conductivity of the p-type thermoelectric conversion layer 14p and the n-type thermoelectric conversion layer 16n can be secured may appropriately set according to the forming material.

Here, in the module 10 in which the connection electrode 18 functions as a metal layer, the thickness of the connection electrode 18 is preferably 3 μm or more and more preferably 6 μm or more. Further, the thickness of the connection electrode 18 is preferably larger than the thickness of the support 12.

In a case where the thickness of the connection electrode 18 satisfies the above condition, sufficient conductivity as an electrode can be secured and also a state in which the module 10 is bent in a bellows-like shape can be suitably maintained due to the plastic deformation of the connection electrode 18.

The module 10 in the example of the drawing has the connection electrode 18 which functions as a metal layer having the low stiffness portion for a simple configuration and easy manufacturing. In other words, in the module 10 in the example of the drawing, the metal layer having the low stiffness portion functions as the connection electrode.

However, the present invention is not limited thereto, and the connection electrode and the metal layer may be formed separately. For example, a metal layer having a low stiffness portion may be formed between the p-type thermoelectric conversion layer 14p and the n-type thermoelectric conversion layer 16n adjacent to each other such that the metal layer is electrically separated from the p-type thermoelectric conversion layer 14p and the n-type thermoelectric conversion layer 16n, and a connection electrode which connects the p-type thermoelectric conversion layer 14p and the n-type thermoelectric conversion layer 16n to each other may be formed on the outer side from the metal layer in the width direction such as a vicinity of an end portion in the width direction such that the connection electrode is electrically separated from the metal layer.

In this case, the thickness of the metal layer may be similar to the thickness of the above-described connection electrode 18 which functions as a metal layer. In addition, regarding the thickness of the connection electrode, the thickness at which sufficient conductivity can be obtained may be appropriately set according to the material forming the connection electrode, the size thereof in the plane direction, and the like.

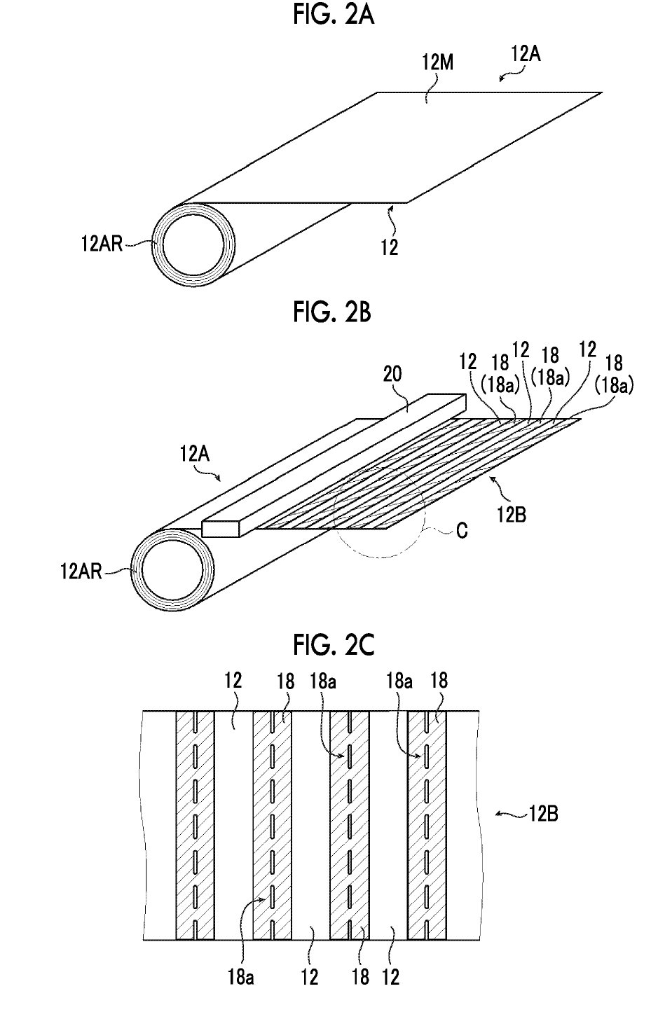

Hereinafter, with reference to conceptual views of FIGS. 2A to 5C, an example of a method of manufacturing a thermoelectric conversion module of the present invention for manufacturing the module 10 of the present invention will be described.

The thermoelectric conversion module in which the connection electrode and the metal layer are separately provided can be basically manufactured in the same manner.

The following manufacturing method is a method using a so-called roll-to-roll process. In the following description, the “roll-to-roll process” is referred to as an “R to R process”.

As already known, the R to R process is a method of pulling out a long object to be treated from a roll formed by winding the object to be treated, subjecting the object to various treatments such as film formation and a surface treatment, while transporting the object to be treated in the longitudinal direction, and winding the treated object in a roll shape.

The module 10 of the present invention can be manufactured by such an R to R process, that is, the module 10 exhibits good productivity, and even in a case of using a thin support 12 of 15 μm or less, good handleability of an intermediate structure in the step in the middle of manufacturing.

In the manufacturing method described below, various operations such as feeding of the support 12 from a roll, transporting of the support 12, and winding of the treated support 12 may be performed by known methods used in a device for performing an R to R process.

First, as shown in FIG. 2A, a roll 12AR formed by winding a laminate 12A in which a metal film 12M such as a copper foil is formed on the entire surface of the support 12 is prepared.

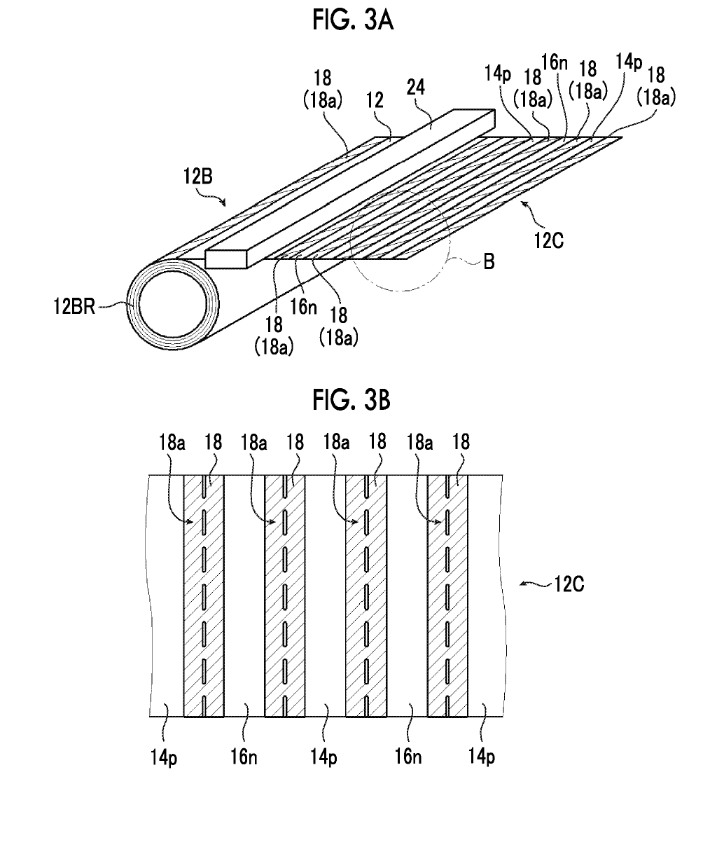

Next, as shown in FIG. 2B, the laminate 12A is pulled out from the roll 12AR and while the laminate is being transported in the longitudinal direction, the metal film 12M is etched using an etching device 20. By etching the metal film 12M, an unnecessary metal film 12M is removed and the connection electrodes 18 having a fixed length are formed at fixed intervals in the longitudinal direction while the low stiffness portions 18a parallel with the width direction are formed in the connection electrodes 18 at fixed intervals in the longitudinal direction. FIG. 2C shows a plan view of a region C in FIG. 2B. In FIGS. 2B to 3B, for the purpose of easy understanding of the configuration, hatching is attached to the connection electrode 18.

Although not shown in FIGS. 2A and 2B, a support 12B on which the connection electrode 18 and the low stiffness portion 18a are formed is wound in a roll shape to form a support roll 12BR.

The formation of the connection electrode 18 and the low stiffness portion 18a by etching the metal film 12M may be performed by a known method. Examples thereof include a method of removing the metal film 12M by ablation using a laser beam, and a method of performing etching by photolithography.

Next, as shown in FIG. 3A, the support 12B on which the connection electrode 18 and the low stiffness portion 18a are formed is pulled out from the support roll 12BR and while the support is being transported in the longitudinal direction, the p-type thermoelectric conversion layer 14p and the n-type thermoelectric conversion layer 16n are alternately formed on portions from which the support 12 is exposed by etching using a film formation device 24. FIG. 3B is a plan view of a region B in FIG. 3A.

Although not shown the drawing, a support 12C on which the p-type thermoelectric conversion layer 14p and the n-type thermoelectric conversion layer 16n are formed is wound in a roll shape to form a support roll 12CR.

The formation of p-type thermoelectric conversion layer 14p and the n-type thermoelectric conversion layer 16n using the film formation device 24 may be performed by a printing method such as screen printing or metal mask printing as described above.

In addition, in a case where the p-type thermoelectric conversion layer 14p and the n-type thermoelectric conversion layer 16n are formed of an inorganic material, the p-type thermoelectric conversion layer 14p and the n-type thermoelectric conversion layer 16n may be formed by a film formation method such as sputtering or vacuum vapor deposition, which is as described above.

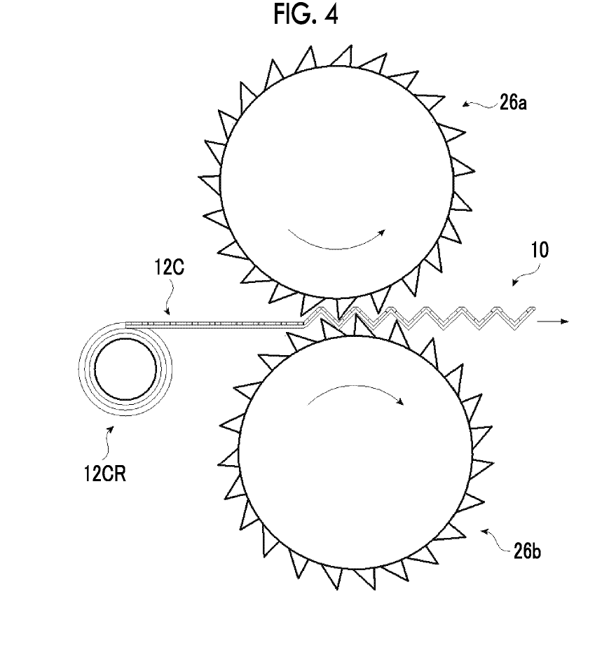

Further, as shown in FIG. 4, the support 12C on which the p-type thermoelectric conversion layer 14p and the n-type thermoelectric conversion layer 16n are formed is pulled out from the support roll 12CR and while the support is being transported in the longitudinal direction, the support 12C is subjected to bending processing by allowing the substrate to pass between a gear 26a and a gear 26b which are engaged with each other and have a pitch narrower than the interval between the low stiffness portions 18a in the longitudinal direction. Thus, the module 10 of the present invention is produced.

As described above, the low stiffness portions 18a parallel with the width direction at fixed intervals in the longitudinal direction are formed on the support 12C. In addition, the gears 26a and 26b have a pitch narrower than the interval between the low stiffness portions 18a. Accordingly, the bellows-like module 10 can be manufactured in which the support 12C is bent in the longitudinal direction by the low stiffness portion 18a and the positions of the top portions of all the mountain-folded portion and the bottom portions of all the valley-folded portions are aligned.

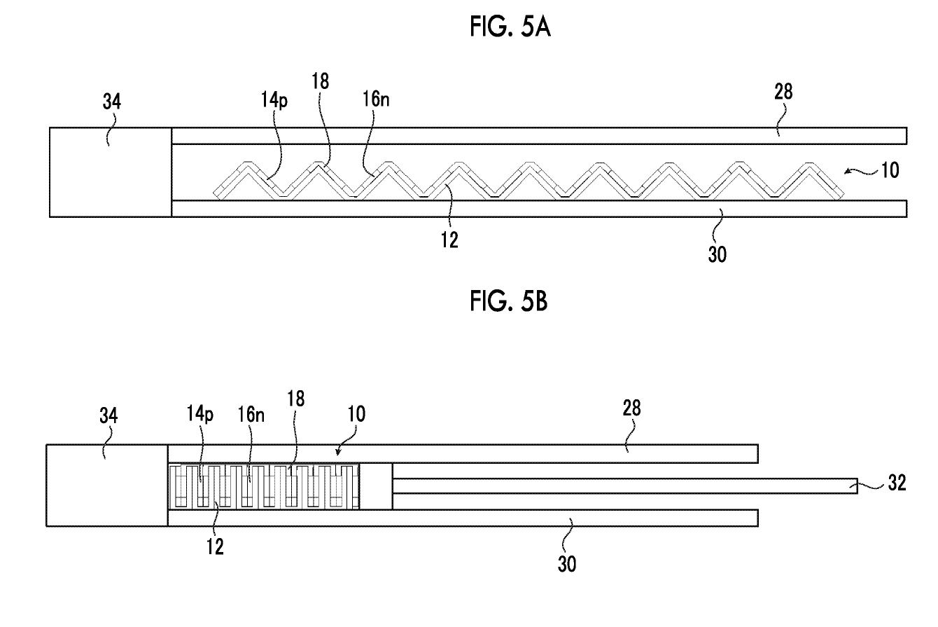

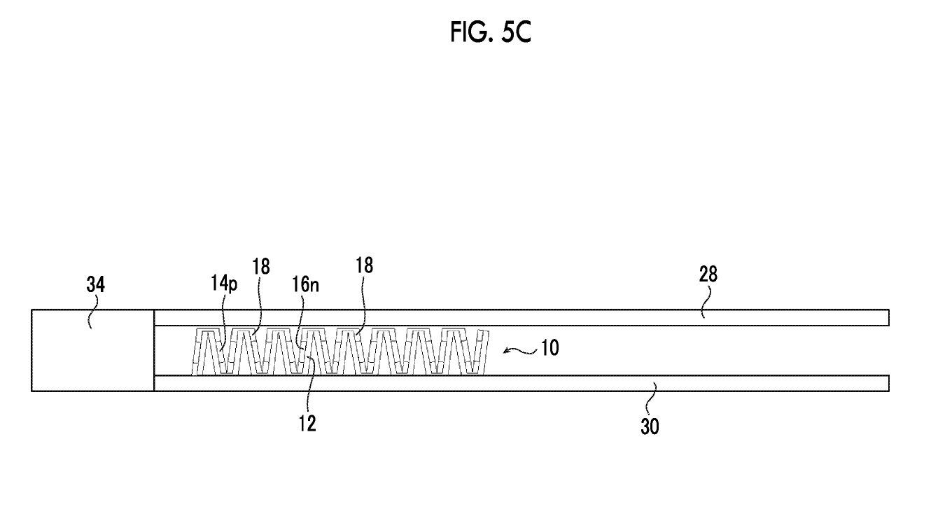

Further, if necessary, as shown in FIG. 5A, the module 10 is inserted between an upper plate 28 and a lower plate 30 having an interval according to the interval between the low stiffness portions 18a in the longitudinal direction, and as shown in FIG. 5B, by pressing a pressing member 32 against a contact portion 34 and compressing the bent module 10 in the longitudinal direction, as shown in FIG. 5C, the bent state of the module 10 may be controlled.

As described above, the module 10 of the present invention can be manufactured with high productivity using an R to R process.

In addition, since the R to R process can be used, for example, the intermediate structure during the manufacturing of the module 10, such as the support 12B on which the connection electrode 18 and the low stiffness portion 18a are formed, or the support 12C on which the p-type thermoelectric conversion layer 14p and the n-type thermoelectric conversion layer 16n are formed, can be handled in a state in which the structure is wound in a roll shape. Therefore, even in a case where the support 12 is a thin film of 15 μm or less, good handleability can be secured.

From the above points, the same is applied to the thermally conductive substrate of the present invention, which will be described later.

A method of manufacturing a thermoelectric conversion module of the present invention is not limited to the above example.

For example, in the above example, the connection electrode 18 and the low stiffness portion 18a are formed at the same time but the present invention is not limited thereto. The connection electrode 18 may be formed, the p-type thermoelectric conversion layer 14p and the n-type thermoelectric conversion layer 16n may be formed, and then the low stiffness portion 18a may be formed.

Alternatively, instead of using the laminate 12A in which the copper foil is formed on the entire surface of the support 12, a common resin film or the like may be used as the support 12, the p-type thermoelectric conversion layer 14p and the n-type thermoelectric conversion layer 16n may be formed on the surface of the support 12 by printing or the like, then the connection electrode 18 may be formed by sputtering or vacuum vapor deposition, and then the low stiffness portion 18a may be formed in the connection electrode 18.

In addition, the bending process can be performed by using, in addition to the method using gears which are engaged with each other, for example, a pressing method using a press plate having roughness narrower than the interval between the low stiffness portions 18a in the longitudinal direction or the like.

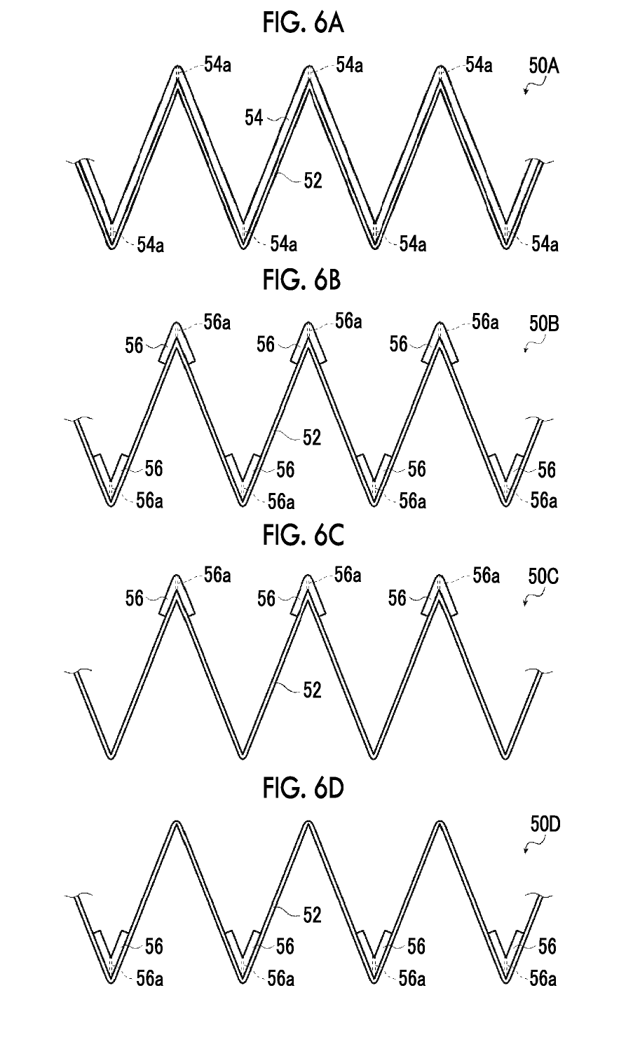

FIG. 6A is a front view conceptually showing an example of a thermally conductive substrate according to the present invention.

A thermally conductive substrate 50A shown in FIG. 6A basically includes a long support 52, and a metal layer 54. In addition, low stiffness portions 54a parallel with the width direction are formed in the metal layer 54. In the example shown in FIG. 6A (FIGS. 6B to 6D), for example, the low stiffness portions 54a (56a) are formed at equal intervals in the longitudinal direction.

The thermally conductive substrate 50A has a bellows-like shape having alternately top portions (mountain portions) and bottom portions (valley portions) which are formed by alternately bending the substrate at the low stiffness portions 54a in a mountain-folded manner and a valley-folded manner.

Such a thermally conductive substrate 50A has a variable length and can be used for various uses requiring thermal conductivity and insulating properties, such as a case where heat has to be dissipated while avoiding contact with an electronic circuit, or the like. Preferably, the thermally conductive substrate is combined with the above-described module 10 of the present invention to form a thermoelectric conversion module according to a second aspect of the present invention.

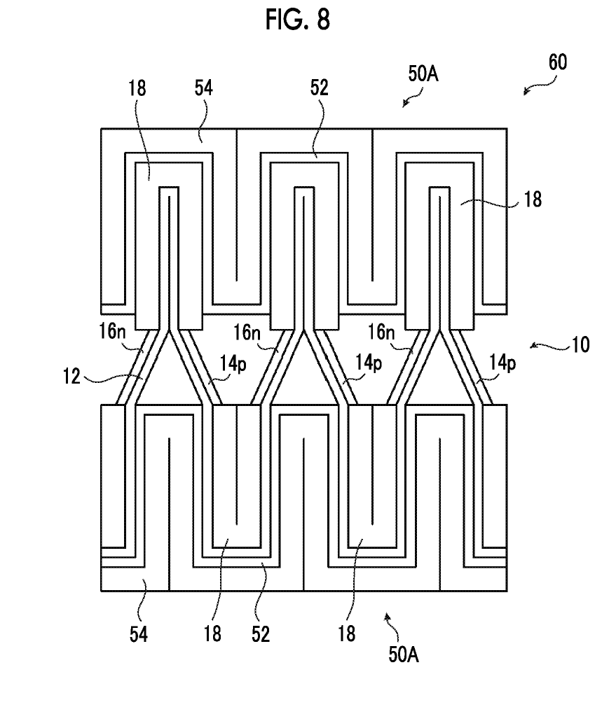

In addition, the thermally conductive substrate 50A shown in FIG. 6A or the like has a bellows-like shape formed by alternately bending the substrate in a mountain-folded manner and a valley-folded manner. However, the thermally conductive substrate of the present invention is not limited thereto. That is, the thermally conductive substrate of the present invention may have a configuration in which the substrate is only mountain-folded in the longitudinal direction, or a configuration in which the substrate is only valley-folded in the longitudinal direction. Accordingly, the thermally conductive substrate of the present invention may have an approximately V shape formed such that only one low stiffness portion is provided and the substrate is mountain-folded at one place in the longitudinal direction, or only one low stiffness portion is provided and the substrate is valley-folded at one place in the longitudinal direction. In addition, for example, a thermoelectric conversion module 60 according to a second aspect of the present invention, which will be described later and is shown in FIG. 8, may have a configuration using a plurality of such approximately V-shaped thermally conductive substrates. Regarding this point, the same is applied to a heat dissipation member, which will be described later.

In the thermally conductive substrate 50A, the support 52 is the same as the support 12 of the above-described module 10 which is long and has flexibility and insulating properties.

In addition, the metal layer 54 and the low stiffness portion 54a are the same as the connection electrode 18 which functions as a metal layer in the above-described module 10.

The thermally conductive substrate of the present invention may have a configuration in which metal layers are formed with intervals in the longitudinal direction, in addition to the configuration in which the metal layer 54 is formed on the entire surface of the support 52 as in the thermally conductive substrate 50A shown in FIG. 6A. In any of the configurations, the low stiffness portions parallel with the width direction formed in the metal layer are formed at fixed intervals in the longitudinal direction.

For example, as in a thermally conductive substrate 50B shown in FIG. 6B, a metal layer 56 in which a low stiffness portion 56a is formed only in a bent portion may be provided. That is, the thermally conductive substrate of the present invention may have a configuration in which the p-type thermoelectric conversion layer 14p and the n-type thermoelectric conversion layer 16n are removed from the module 10 shown in FIG. 1A.

In addition, as in a thermally conductive substrate 50C shown in FIG. 6C, a metal layer 56 in which a low stiffness portion 56a is formed only in a mountain fold portion may be provided. Further, as shown in a thermally conductive substrate 50D shown in FIG. 6D, a metal layer 56 in which a low stiffness portion 56a is formed only in a valley fold portion may be provided.

In the specification, for the sake of convenience, the mountain fold portion represents a portion formed by bending such that the support becomes the inner side, and the valley fold portion represents a portion formed by bending such that the support becomes the outer side, respectively. Accordingly, in the mountain fold portion, the metal layer 54 and the metal layer 56 are formed in a protruding shape and in the valley fold portion, the metal layer 54 and the metal layer 56 are formed in a recessed shape.

Such a thermally conductive substrate can be basically manufactured in the same manner as in the manufacturing of the above-described module 10 except that the thermoelectric conversion layer is not formed.

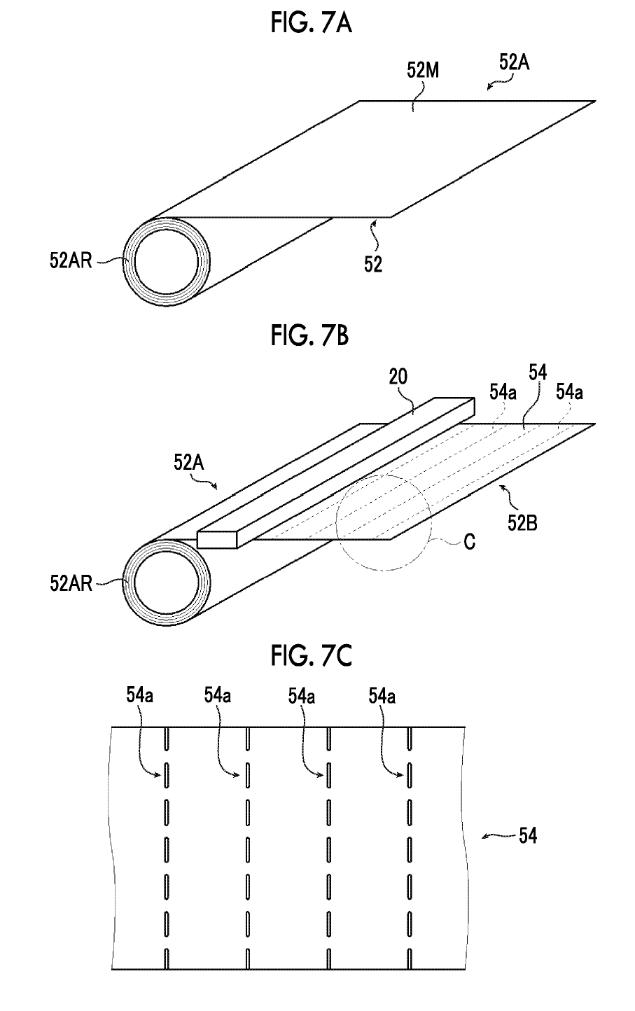

That is, as shown in FIG. 7A, a roll 52AR formed by winding a laminate 52A in which a metal film 52M such as a copper foil is formed on the entire surface of the support 52 is first prepared.

Next, as shown in FIG. 7B, the laminate 52A is pulled out from the roll 52AR and while the laminate is transported in the longitudinal direction, the metal film 52M is etched using an etching device 20.

In the example, the metal film 52M becomes the metal layer 54 as it is. By etching the metal film 52M, that is, the metal layer 54, the low stiffness portions 54a parallel with the width direction are formed on the metal layer 54 at fixed intervals in the longitudinal direction. FIG. 7C shows a plan view of a region C in FIG. 7B.

Although not shown in the drawing, a support 52B on which the low stiffness portion 54a is formed on the metal layer 54 is wound in a roll shape.

The etching can be performed using the same method as in the manufacturing of the above-described module 10.

As shown in FIGS. 6B to 6D, in a case where the thermally conductive substrates 50B to 50D in which the metal layers 56 are formed to be separated from each other in the longitudinal direction are manufactured, unnecessary regions of the metal film 52M may be removed by etching while performing etching for forming the low stiffness portion 54a.

Subsequently, the thermally conductive substrate 50A may be produced in the same manner as in the production of the above-described module 10 except that the p-type thermoelectric conversion layer 14p and the n-type thermoelectric conversion layer 16n are not formed.

That is, the support 52B on which the low stiffness portion 18a is formed is wound in a roll shape and then the support 52B is pulled out. While transporting the support in the longitudinal direction, as shown in FIG. 4, the support 52B is subjected to bending processing by allowing the support to pass between the gears 26a and 26b which have the same pitch as the interval between the low stiffness portions 54a in the longitudinal direction and are engaged with each other and thus the thermally conductive substrate 50A of the present invention is produced.

Further, if necessary, as shown in FIGS. 5A to 5C, the bent state of the thermally conductive substrate 50A may be controlled by compressing the thermally conductive substrate 50A in the longitudinal direction.

FIG. 8 is a front view conceptually showing a second aspect of the thermoelectric conversion module of the present invention.

A thermoelectric conversion module 60 has a configuration in which the above-described module 10 shown in FIG. 1A is used as a module main body, and the above-described thermally conductive substrate 50A shown in FIG. 6A is laminated on both surfaces of the module 10 such that the roughness of the module 10 and the roughness of the thermally conductive substrate 50A are fitted to each other and the support 52 is directed to the module 10, and further compressed in the longitudinal direction. In FIG. 8, the low stiffness portion 18a and the low stiffness portion 54a are omitted.

That is, in the thermoelectric conversion module 60 shown in FIG. 8, the mountain fold portion of the module 10 and the mountain fold portion of the thermally conductive substrate 50A are fitted to each other on the side of the module 10 on which the connection electrode 18 or the like is provided, the valley fold portion of the module 10 and the mountain fold portion of the thermally conductive substrate 50A are fitted to each other on the support 12 side of the module 10, and thus the module 10 and the thermally conductive substrate 50A are laminated.

In the following description, the “thermoelectric conversion module 60” is also referred to as a “module 60”.

In the module 10 shown in FIG. 1A, in a case of compression as shown in FIGS. 5A to 5C, a short circuit caused by contact between the p-type thermoelectric conversion layer 14p and the n-type thermoelectric conversion layer 16n and a short circuit caused by unnecessary contact between the connection electrodes 18 may be caused.

In contrast, since the support 52 having insulating properties is directed to the module 10 and the thermally conductive substrate 50A is laminated in the module 60 shown in FIG. 8, contact between the connection electrodes 18 is avoided on the surface from which the connection electrode 18 is exposed outwardly by bending and on which contact between the connection electrodes 18 is a problem. That is, in the mountain fold portion in which the support 12 becomes the inner side and the connection electrode 18 is exposed outwardly, contact between the connection electrodes 18 is avoided.

In addition, the mountain fold portions and the valley fold portions of the module 10 are compressed in the longitudinal direction through the thermally conductive substrate 50A (support 52 and metal layer 54) having a thickness. Accordingly, the end portions of the p-type thermoelectric conversion layer 14p and the n-type thermoelectric conversion layer 16n facing each other in the mountain fold portion side are separated from each other by this thickness. In addition, the end portions of the p-type thermoelectric conversion layer 14p and the n-type thermoelectric conversion layer 16n facing each other on the valley fold portion side are separated from each other by the thickness of the connection electrode 18 of the module 10. The p-type thermoelectric conversion layer 14p and the n-type thermoelectric conversion layer 16n facing each other are arranged so as to form an approximately V shape by the separation by the thickness of each member and as a result, a short circuit caused by unnecessary contact can be prevented.

In addition, in the module 60, the metal layer 54 of the thermally conductive substrate 50A formed of a metal and having high thermal conductivity is positioned so as to cover the connection electrode 18 of the module 10. Therefore, in the module 60, heat can be effectively transferred to the module 10 from the heat source on the high temperature heat source side and the heat of the module 10 can be effectively radiated on the low temperature heat source side.

In the thermoelectric conversion module shown in FIG. 8, the thermally conductive substrate 50A is laminated on both surfaces of the module 10 while the thermally conductive substrate is directed to the support 52.

However, the second aspect of the thermoelectric conversion module of the present invention is not limited thereto and the thermally conductive substrate 50A may be laminated on only one surface of the module 10 while the thermally conductive substrate is directed to the support 52. However, in this case, in order to prevent the above-described unnecessary contact between the connection electrodes 18 and contact between the p-type thermoelectric conversion layer 14p and the n-type thermoelectric conversion layer 16n facing each other by valley fold, it is required to laminate the thermally conductive substrate 50A on the surface from which the connection electrode 18 is exposed outwardly by bending of the module 10, that is, the surface of the mountain fold portion side of the module 10.

In the second aspect of the thermoelectric conversion module of the present invention, even in a case of using the thermally conductive substrates 50B to 50D in which the metal layer is formed in only the bent portion shown in FIGS. 6B to 6D, the same effects as described above can be obtained.

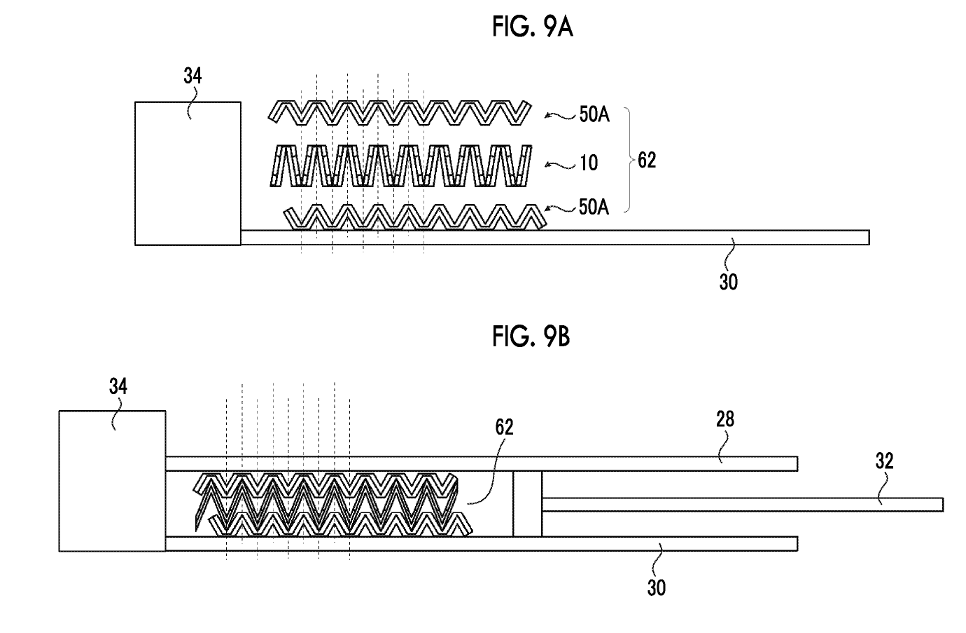

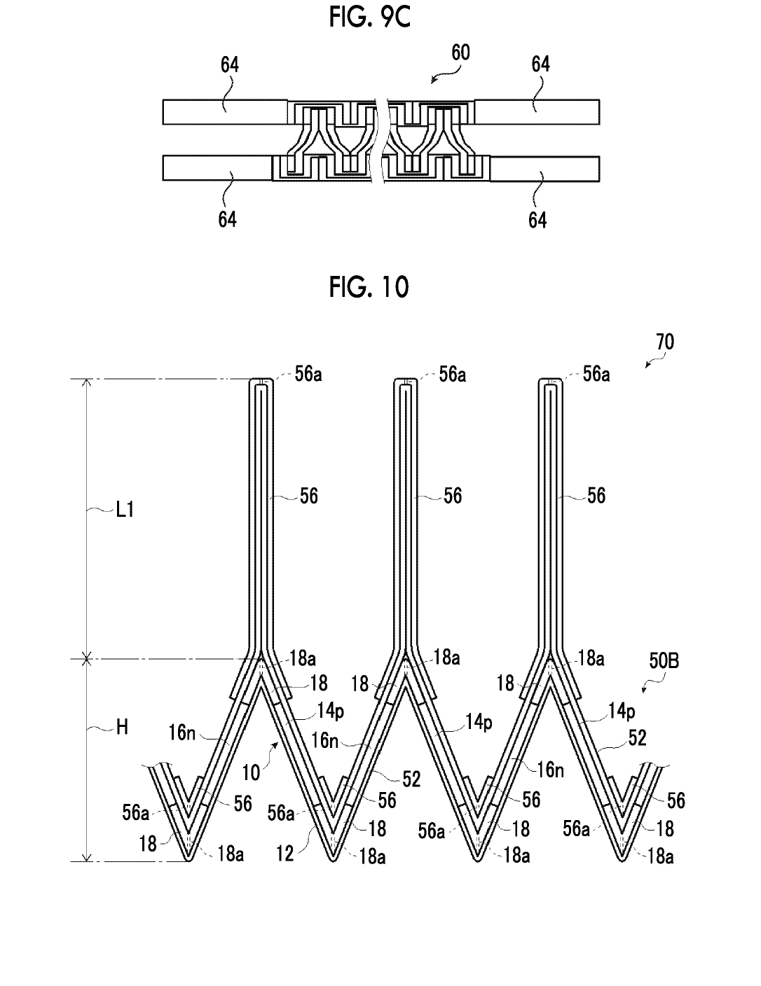

The method of manufacturing the module 60 shown in FIG. 8 will be described with reference to conceptual views of FIGS. 9A to 9C.

The module 60 can be manufactured basically in the same manner as in the method of manufacturing the module 10 shown in FIGS. 5A to 5C.

First, as described above, the module 10 and the thermally conductive substrate 50A are produced.

Next, as shown in FIG. 9A, the roughness of the module 10 and the roughness of the thermally conductive substrate 50A are fitted to each other on the lower plate 30 and the thermally conductive substrate 50A is laminated on both surfaces of the module 10 to form a laminate 62. In the present invention, the laminate 62 may be used as a thermoelectric conversion module.

Next, as shown in FIG. 9B, the upper plate 30 is arranged at a position according to the interval between the low stiffness portions 18a and the thickness of the thermally conductive substrate 50A (the thickness of the support 52 and the metal layer 54) on the laminate 62 on which the thermally conductive substrate 50A is laminated on the both surfaces of the module 10 by the upper plate 28, the laminate is pressed against the contact portion 34 by the pressing member 32, and the laminate 62 is compressed in the longitudinal direction to produce the module 60.

Further, the compressed laminate 62 is taken out from between the upper plate 28 and the lower plate 30 and is fixed by a frame 64 such that the connection electrode 18 is compressed in the longitudinal direction to form the module 60.

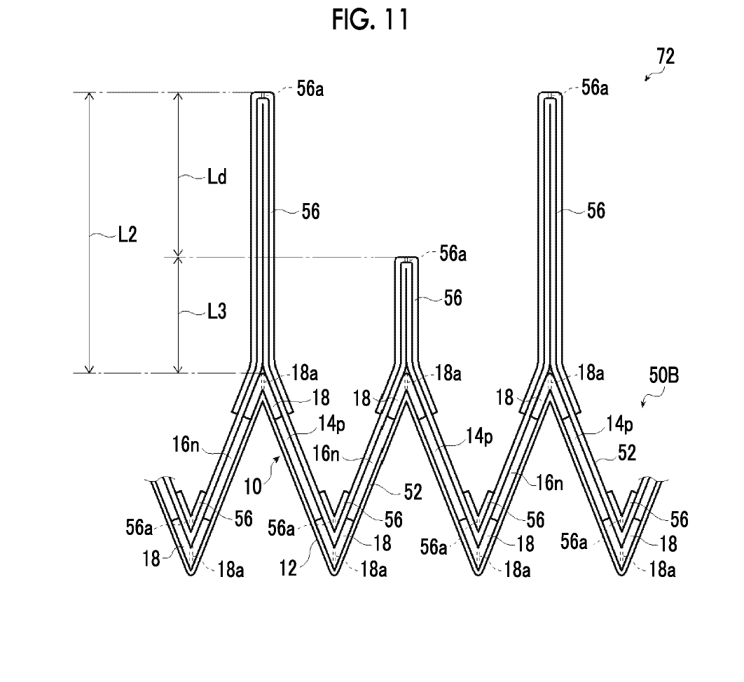

FIG. 10 is a view conceptually showing another example of the second aspect of the thermoelectric conversion module according to the present invention.

In the module 60 shown in FIG. 8, the module 10 shown in FIG. 1A is used as a module main body and the thermally conductive substrate 50A in which the metal layer 54 is provided on the entire surface shown in FIG. 6A is provided on both surfaces of the module 10 by fitting the roughness and directing the thermally conductive substrate to the support 52.

In contrast, a thermoelectric conversion module 70 shown in FIG. 10 is formed such that the module 10 shown in FIG. 1A is used as a module main body and the thermally conductive substrate 50B in which the metal layer 56 is provided only in the mountain fold portion and the valley fold portion shown in FIG. 6B is laminated on the surface of the module 10 on which the thermoelectric conversion layer of the module 10 or the like is formed by fitting the roughness and directing the thermally conductive substrate to the support 52.

In the following description, the “thermoelectric conversion module 70” is referred to as the “module 70”. In addition, in the following description, the surface on which the thermoelectric conversion layer or the like is formed in the thermoelectric conversion module is referred to as an “upper surface” and the opposite surface is referred to as a “rear surface”.

In the module 60 shown in FIG. 8, the thermally conductive substrate 50A corresponds to only the connection electrode 18 in a bellows-like shape of which the height of the roughness is low compared to the roughness of the bellows of the module 10.

In contrast, in the module 70 shown in FIG. 10, the thermally conductive substrate 50B has a bellows-like shape having roughness having a much higher height than that of the roughness of the bellows of the module 10. Accordingly, the facing surfaces of the top portion of the mountain fold portion of the thermally conductive substrate 50B and the top portion of the surface side of the module 10 are separated from each other. That is, the top portion of the mountain fold portion of the thermally conductive substrate 50B significantly protrudes from the top portion of the surface side of the module 10.

In the following description, the “top portion of the mountain fold portion of the thermally conductive substrate” is referred to as a “top portion of the thermally conductive substrate” and the “top portion of the surface side of the module” is referred to as a “top portion of the module”.

In addition, regions protruding from the top portions of the module 10 in the mountain fold portions of the thermally conductive substrate 50B are pressed in the longitudinal direction and the support 52 folded at the top portions is in close contact therewith.

Further, in the module 70, the metal layer 56 which is provided in the mountain fold portion of the thermally conductive substrate 50B is formed from the region of the top portion side of the module 10, which becomes the module main body, corresponding to the connection electrode 18 to the region corresponding to the connection electrode 18 on the top portion side reached to the top portion of the thermally conductive substrate SOB and folded in the longitudinal direction. That is, the metal layer 56 is entirely formed in the region protruding from the top portion of the module 10 of the thermally conductive substrate 50B. Accordingly, in the thermally conductive substrate 50B using the module 70, a wide metal layer 56 and a narrow metal layer 56 are alternately formed.

In addition, the region of the module 10 in which the thermoelectric conversion layer is formed is a region in which the metal layer 56 of the thermally conductive substrate 50B is not present in the most part excluding a portion in which the metal layer 56 is formed in the valley fold portion.

As already known, metal has high thermal conductivity. Accordingly, as described above, the height of the roughness of the thermally conductive substrate 50B is significantly increased compared to the module 10, and the top portion of the thermally conductive substrate 50B is caused to protrude from the top portion of the module 10 so as to provide the metal layer 56 in the region protruding from the top portion of the module 10 of the thermally conductive substrate 50B. Thus, the thermally conductive substrate 50B is caused to function as a heat dissipating fin so that a function as heat dissipation means can be significantly increased. Thus, the power generation amount of the thermoelectric conversion module can be increased by increasing a temperature difference in the thermoelectric conversion layer.

In addition, the thermoelectric conversion module of the present invention can be wound around a circumference surface of a cylindrical object such as a pipe using good flexibility while setting the longitudinal direction as a circumferential direction. In this case, since the mountain fold portions of the thermally conductive substrate 50B are spaced apart to separate the top portions from each other in the module 70, a higher heat dissipation effect can be obtained.

Further, since the thermally conductive substrate 50B and the module 10 are laminated by directing the support 52 of the thermally conductive substrate 50B to the surface of the module 10 so as to cover the surface of the module 10 by the support 52, it is possible to allow the support 52 to function as an insulating layer. Therefore, as a preferable aspect, even in a case where the module 10 is compressed in the longitudinal direction, it is possible to prevent a short circuit caused by contact between the connection electrodes 18 of the mountain fold portions, and contact between the p-type thermoelectric conversion layer 14p and n-type thermoelectric conversion layer 16n.

In addition, by providing a region of the thermally conductive substrate 50B in which the metal layer 56 is not provided in the region of the module 10 in which the thermoelectric conversion layer is formed, a temperature difference in the thermoelectric conversion layer can be secured.

In the module 70, the protrusion amount of the top portion of the thermally conductive substrate 50B with respect to the top portion of the module 10 may be appropriately set according to the size of the module 70, a place where the module 70 is to be installed, and the like.

According to the study of the present inventors, as shown in FIG. 10, in a case where the height of the roughness of the module 10 is set to H, and the distance between the top portion of the module 10 and the top portion of the thermally conductive substrate 50B, that is, the protrusion amount of the top portion of the thermally conductive substrate 50B from the top portion of the module 10 is set to L1, it is preferable that the protrusion amount L1 is 0.5 to 5 times the height H.

That is, it is preferable to satisfy “0.5H≤L1≤5H”.

By setting the protrusion amount L1 of the top portion of the thermally conductive substrate 50B to 0.5 times or more the height H of the roughness of the module 10, a sufficient heat dissipation effect is obtained and thus the power generation amount can be improved.

In addition, in a case where the protrusion amount L of the top portion of the thermally conductive substrate 50B is set to 5 times or more the height of the roughness of the module 10, even if the protrusion amount is further increased, the effect of improving the heat dissipation effect is weak. Accordingly, by setting the protrusion amount L1 of the top portion of the thermally conductive substrate 50B to 5 times or less the height of the roughness of the module 10, the size of module 70 is prevented from being unnecessarily increased. Thus, a degree of freedom of an installation place can be increased and the use of the module 70 can be expanded.

In the configuration in which the top portion of the thermally conductive substrate 50B protrudes from the top portion of the module 10, as in a thermoelectric conversion module 72 shown in FIG. 11, the protrusion amounts of the top portions, that is, the heights of the top portions of the thermally conductive substrate 50B from the top portion of the module 10 may be different. That is, the thermally conductive substrate 50B may have roughness having different heights (mountain portions having different heights).

In this manner, since the thermally conductive substrate 50B has top portions having different heights, air easily flows in the protruding portion of the thermally conductive substrate 50B from the module 10, and thus the heat dissipation effect by the thermally conductive substrate 50B can be improved.

In a case where the thermally conductive substrate 50B has top portions having different heights, the top portions having two kinds or more of heights may be provided. In addition, a change in the height of the top portion may be periodic for example, as in a case where roughness having two kinds of heights is alternately formed, a case where roughness having three kinds of heights is formed in order, or the like, or non-periodic as in a case where the height of the top portion irregularly changes in the longitudinal direction or the like.

Accordingly, in the example, the interval between the low stiffness portions 56a in the longitudinal direction in the thermally conductive substrate 50B is not a fixed interval and is an interval which becomes a pattern repeated according to a change in the height of the top portion of the thermally conductive substrate 50B, or an irregular interval.

In a case where the thermally conductive substrate 50B has top portions having different heights, a difference between the heights of the top portions may be appropriately set according to the size of the module 70, a place where the module 70 is to be installed, and the like.

According to the study of the present inventors, in the thermally conductive substrate 50B, in a case where the protrusion amount of the highest top portion is set to a maximum protrusion amount L2, and the protrusion amount from the top portion of the module 10 excluding the highest top portion is set to L3, a difference Ld between the maximum protrusion amount L2 and the protrusion amount L3 is preferably ½ or more of the maximum protrusion amount L2.

That is, it is preferable to satisfy “Ld≥0.5L2 (where, Ld=L2−L3)”.

In the thermally conductive substrate 50B having top portions having different heights, the difference Ld between the maximum protrusion amount L2 and the protrusion amount L3 is set to ½ or more of the maximum protrusion amount L2, and thus air accumulation is suitably prevented in the protruding portions of the thermally conductive substrate 50B in the module 72. Thus, a larger power generation amount can be obtained by improving the heat dissipation effect.

In the module 70 shown in FIG. 10 and the module 72 shown in FIG. 11, the thermally conductive substrates of the present invention may be also provided on both surfaces of the module 10. At this time, the same thermally conductive substrate may be provided on the both surfaces of the module 10 or different thermally conductive substrates may be provided on the rear surface side and the upper surface side of the module 10.

In a case where a different thermally conductive substrate is used on the rear surface from the thermally conductive substrate on the upper surface, the thermally conductive substrate provided on the rear surface side may have a bellows-like shape of which the roughness is higher than the roughness of the bellows of the module 10 as in the example shown in FIG. 10, may have a bellows-like shape of which the height of the roughness is the same as the height of the roughness of the bellows of the module 10, or may have a bellows-like shape of which the roughness is lower than the roughness of the bellows of the module 10, for example, as shown in example in FIG. 8, may have a bellows-like shape of which the roughness has a height corresponding to the connection electrode 18.

The configuration in which the top portion of the thermally conductive substrate protrudes from the top portion of the module 10 as described above can be used in various thermally conductive substrates of the present invention in addition to the thermally conductive substrate 50B having an interval in the longitudinal direction and having the metal layer in the mountain fold portion and the valley fold portion, as long as the metal layer is provided in the mountain fold portion.

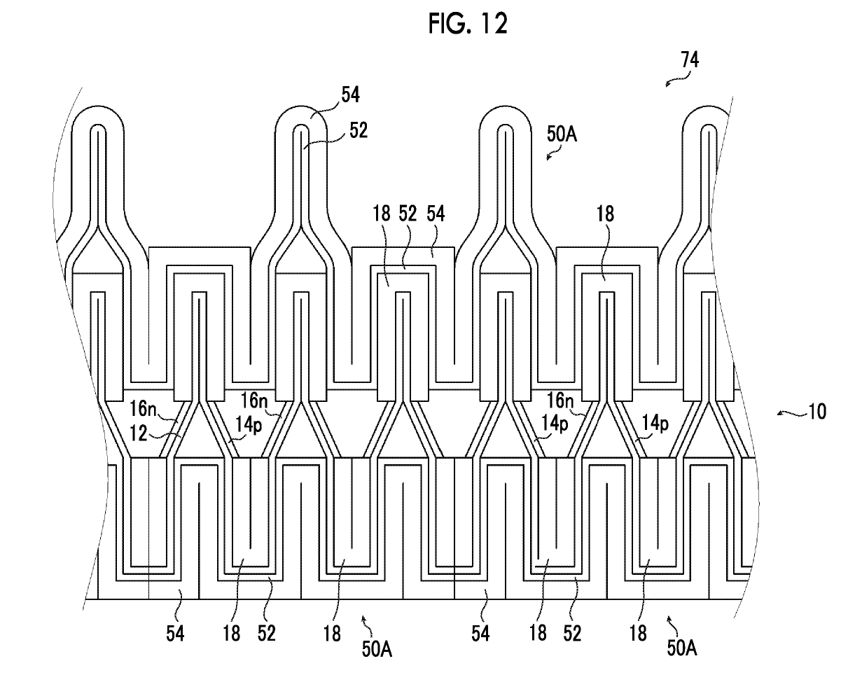

For example, as in the module 60 shown in FIG. 8, the above configuration can be used even in a thermoelectric conversion module using the thermally conductive substrate 50A in which the metal layer 54 is provided on the entire surface of the support 52. As an example, a thermoelectric conversion module 74 in FIG. 12 is shown.

Even in this configuration, by the mountain fold portion of the thermally conductive substrate 50A having the top portion protruding from the top portion of the module 10 and having the metal layer 54 formed therein, the heat dissipation effect can be improved. In FIG. 12, the low stiffness portion 18a and the low stiffness portion 54a are omitted.

In addition, in this example, since the thermally conductive substrate 50A has top portions having different heights, the heat dissipation effect can be further improved. Further, the mountain fold portions of the thermally conductive substrate 50A are separated by being wound around a pipe or the like and thus a higher heat dissipation effect can be obtained.

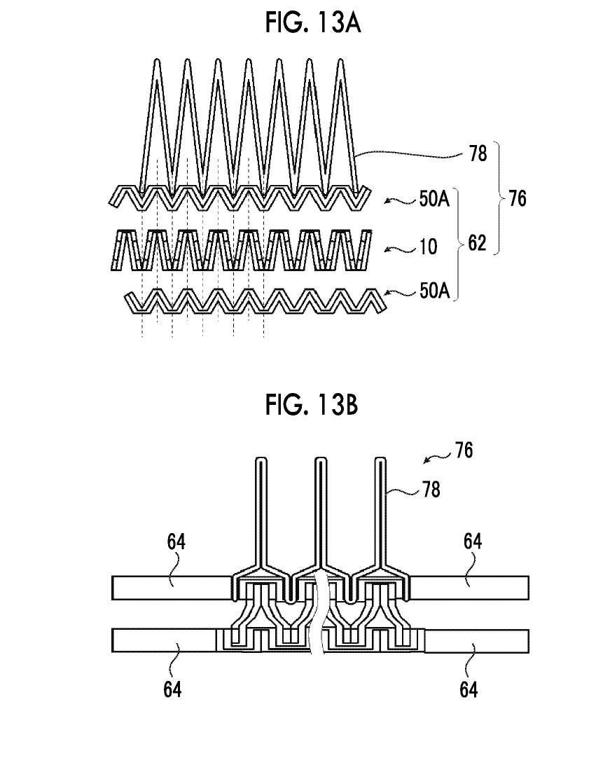

FIGS. 13A and 13B show another example of the second aspect of the thermoelectric conversion module according to the present invention.

A thermoelectric conversion module 76 is formed by laminating a bellows-like heat dissipation member 78 on the thermally conductive substrate 50A on the upper surface side in the module 60 shown in FIGS. 8, 9A, and 9B.

In the following description, the “thermoelectric conversion module 76” is referred to as a “module 76”.

The heat dissipation member 78 is obtained by alternately mountain-folding and valley-folding a long plate-like material having a thermal conductivity to be formed in a bellows-like shape. Accordingly, the heat dissipation member 78 also has a top portion and a bottom portion alternately in the longitudinal direction by bellows-like folding.

The heat dissipation member 78 has a low stiffness portion parallel with the width direction similar to the low stiffness portion 54a for the same reasons as in the thermally conductive substrate 50A and mountain folding and valley folding may be performed at the low stiffness portion.

As the material forming the heat dissipation member 78, various metal materials such as aluminum and copper may be used.

Such a bellows-like heat dissipation member 78 may be manufactured by a known method such as press processing. In addition, the heat dissipation member can be manufactured by methods similar to the manufacturing methods of the module 10 and the thermally conductive substrate 50A or the like.

The module 76 is formed in the following manner. As in FIG. 9A described above, the roughness of the module 10 and the roughness of the thermally conductive substrate 50A are fitted to each other and the thermally conductive substrate 50A is laminated on both surfaces of the module 10 to form the laminate 62. Further, the roughness of the thermally conductive substrate 50A and the roughness of the heat dissipation member 78 are fitted to each other and the heat dissipation member 78 is laminated on the thermally conductive substrate 50A provided on the surface side to form the module 76.

In the example shown in FIG. 13B, as a preferable aspect, as shown in FIG. 13B, the module 76 is compressed in the longitudinal direction as shown in FIG. 9B described above. Further, the portions of the heat dissipation member 78 protruding from the thermally conductive substrate 50A are also compressed in the longitudinal direction and the folded heat dissipation members are brought into close contact with each other. Further, if necessary, the frame 64 is fixed such that the compressed module 76 is compressed in the longitudinal direction.

Here, as shown in FIGS. 13A and 13B, the heat dissipation member 78 has a bellows-like shape having very high roughness compared to the roughness of the bellows of the thermally conductive substrate 50A. Accordingly, the facing surfaces of the top portion of the mountain fold portion of the thermally conductive substrate 50A and the top portion of the mountain fold portion of the heat dissipation member 78 are separated. That is, the mountain fold portion of the heat dissipation member 78 protrudes from the top portion of the thermally conductive substrate 50A.

Therefore, the module 76 can obtain a high heat dissipation effect by the mountain fold portion of the heat dissipation member 78 protruding from the top portion of the thermally conductive substrate 50A. Thus, the module 76 causes a large temperature difference in the thermoelectric conversion layer so that the power generation amount of the thermoelectric conversion module can be increased.

As described above, in the thermally conductive substrate 50A, the metal layer 54 is positioned on the upper side in the drawing. Accordingly, the heat dissipation member 78 formed of metal or the like and having good thermal conductivity is laminated in contact with the metal layer 54. Due to this viewpoint, the module 76 can obtain a high heat dissipation effect.

In the module 76 having the heat dissipation member 78, a preferable protrusion amount of the heat dissipation member 78 from the top portion of the thermally conductive substrate 50A is similar to the protrusion amount in the above-described module 70.

As in the module 76, in the configuration in which the heat dissipation member 78 protrudes from the top portion of the thermally conductive substrate 50A, it is preferable that the heat dissipation member 78 has roughness having different heights (mountain fold portions). Thus, similar to the above module 72, air flowing is good in the protruding portion of the heat dissipation member 78 from the thermally conductive substrate 50A and thus a higher heat dissipation effect can be obtained.

In the module 76 having the heat dissipation member 78, in a case where roughness having different heights is provided, a preferable difference between the heights of the mountain fold portions is similar to the difference in the above-described module 72.

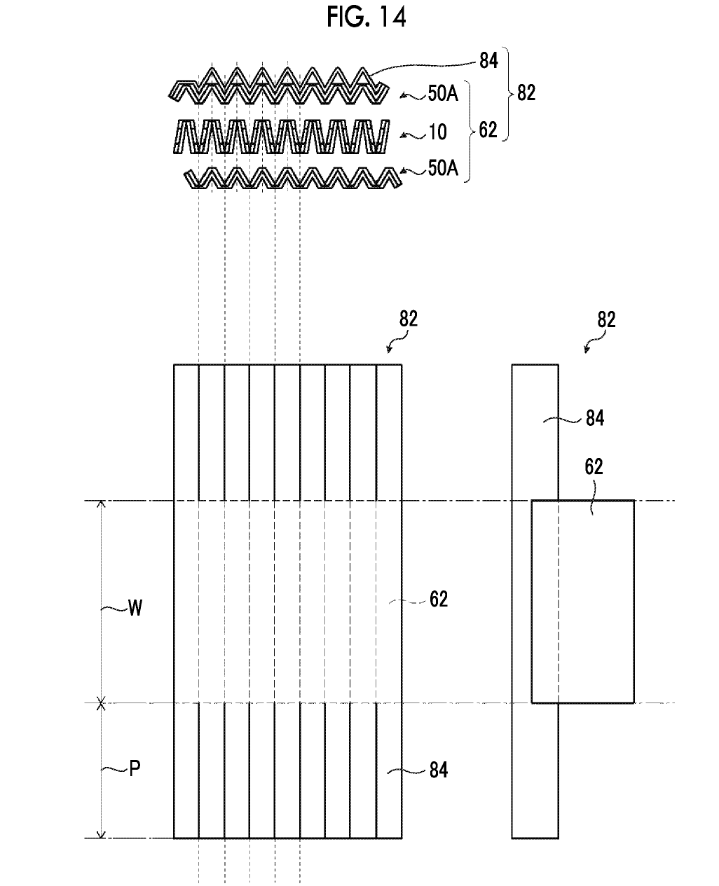

FIG. 14 is a view conceptually showing still another example of the thermoelectric conversion module according to the second aspect of the present invention.

As in the module 76 shown in FIG. 13B above, a thermoelectric conversion module 82 is formed by laminating a bellows-like heat dissipation member 84 on the thermally conductive substrate 50A on the upper surface side in the module 60 shown in FIGS. 9A and 9B.

In the lower side of FIG. 14, the left side is a plan view as the thermoelectric conversion module 82 is seen from the upper side, that is, as the heat dissipation member 84 is seen from the upper side, and the right side is a side view as the thermoelectric conversion module 82 is seen from the longitudinal direction.

In the following description, the “thermoelectric conversion module 82” is also referred to as a “module 82”.

The heat dissipation member 84 is formed in a bellows-like shape by alternately mountain-folding and valley-folding a long plate-like material having a thermal conductivity as in the formation of the heat dissipation member 78.

Accordingly, the heat dissipation member 78 also has a top portion and a bottom portion alternately in the longitudinal direction by bellows-like folding. In addition, the heat dissipation member 84 also has a low stiffness portion parallel with the width direction similar to the low stiffness portion 54a for the same reasons as in the thermally conductive substrate 50A and mountain folding and valley folding may be performed at the low stiffness portion.

The module 82 can be produced in the same manner as in the production of the module 76 shown in FIG. 13B. That is, the roughness of the module 10 and the roughness of the thermally conductive substrate 50A are fitted to each other and the thermally conductive substrate 50A is laminated on both surfaces of the module 10 to form the laminate 62. Further, the roughness of the thermally conductive substrate 50A and the roughness of the heat dissipation member 78 are fitted to each other and the heat dissipation member 84 is laminated on the thermally conductive substrate 50A on the surface side (upper side in the drawing) to form the module 82.

The module 82 is also preferably compressed in the longitudinal direction. Further, if necessary, the module may be fixed by using a frame so as to maintain the compression of the compressed module 82.

Here, as shown in the lower section in FIG. 14, in the module 82, the size of the roughness of the heat dissipation member 84 is substantially the same as the size of the roughness of the thermally conductive substrate 50A. However, the heat dissipation member protrudes from the module 10 (laminate 62) which becomes a module main body in the width direction. That is, in the upper section in FIG. 14, the heat dissipation member 84 protrudes from the module 10 in a direction perpendicular to a paper surface.

In the module 82, a region protruding from the module 10 in the width direction of the heat dissipation member 84 functions as a heat dissipating fin and thus a high heat dissipation effect can be obtained. Thus, the module 82 increases a temperature difference in the thermoelectric conversion layer and thus the power generation amount of the thermoelectric conversion module can be increased.

As described above, in the thermally conductive substrate 50A, the metal layer 54 is positioned on the upper side in the drawing. Accordingly, the heat dissipation member 84 formed of metal or the like and having good thermal conductivity is laminated in contact with the metal layer 54. From the viewpoint, a high heat dissipation effect can be obtained in the module 82.

In the module 82, the protrusion amount of the heat dissipation member 84 from the module 10 in the width direction may be appropriately set according to the size of the module 82, a place where the module 82 to be installed, or the like.

According to the study of the present inventors, as shown on the lower section in FIG. 14, in a case where the width of the module 10 (the size in the width direction) is set to W and the protrusion amount of the heat dissipation member 84 from the module 10 in the width direction is set to P, the protrusion amount P is preferably 0.1 to 10 times the width W of the module 10.

That is, it is preferable to satisfy “0.1 W≤P≤10 W”. The protrusion amount is a protrusion amount of the heat dissipation member 84 from the thermally conductive substrate 50A in the width direction in a case where the thermally conductive substrate 50A protrudes in the width direction from the module 10.

By setting the protrusion amount P of the heat dissipation member 84 in the width direction to be 0.1 times or more the width W of the module 10, a sufficient heat dissipation effect is obtained and thus the power generation amount can be improved.

In addition, in a case where the protrusion amount P of the heat dissipation member 84 in the width direction is set to 10 times or more the width W of the module 10, even if the protrusion amount is further increased, the heat dissipation effect is weal. Accordingly, by setting the protrusion amount P of the heat dissipation member 84 to be 10 times or less the width W of the module 10, the size of module 82 is prevented from being unnecessarily increased. Thus, a degree of freedom of an installation place can be increased and the use of the module 82 can be expanded.

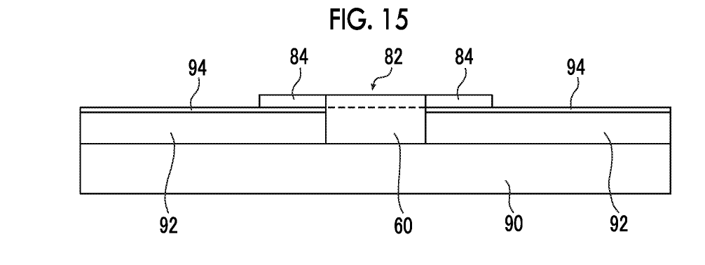

FIG. 15 is a conceptual view for illustrating an example of usage of the module 82 in which the heat dissipation member 84 protrudes from the module 10 in the width direction. As clearly seen from the protrusion direction of the heat dissipation member 84, in FIG. 15, the transverse direction in the drawing is a width direction and thus a direction perpendicular to a paper surface is a longitudinal direction.

As shown in FIG. 15, in a case of using the module 82, it is preferable that the module 82 is placed on a high temperature heat source 90, a heat insulating material 92 is placed in regions other than a region where the module 82 is placed in the heat source 90, a thermally conductive member 94 formed of the same metal as the heat dissipation member 84 is placed on the heat insulating material 92, and the region of the heat dissipation member 84 protruding from the module 10 is placed on the heat insulating material 94.

For the heat insulating material 92, various known materials such as glass wool can be used and commercially available heat insulating materials may be used.

By using the module 82 as shown in FIG. 15, the region of the heat dissipation member 84 protruding from the module 10 in the width direction can be brought into contact with the heat insulating material 94 at almost room temperature.

Accordingly, since the protruding region of the heat dissipation member 84 is prevented from being heated by the high temperature heat source 90 to keep the temperature at almost room temperature, a sufficient temperature difference can be generated in the thermoelectric conversion layer of the module 10 and as a result, the power generation amount by the module 82 can be increased.

In the module 82 in which the heat dissipation member 84 protrudes from the module 10 in the width direction, the mountain fold portion of the heat dissipation member 84 may be caused to significantly protrude from the thermally conductive substrate 50A by setting the roughness of the heat dissipation member 84 to be higher than the roughness of the thermally conductive substrate 50A.

Further, the mountain fold portion of the heat dissipation member 84 protruding from the thermally conductive substrate 50A may have roughness having different heights.

In addition, the heat dissipation member 84 may protrude not only from both sides in the width direction but also from one side in the width direction.

Such a configuration can be used in a thermoelectric conversion module not having a heat dissipation member as the module 60 shown in FIG. 8, the module 70 shown in FIG. 10, the module 72 shown in FIG. 11I, and the module 74 shown in FIG. 12.

That is, in the module 60, the module 70, and the like, the thermally conductive substrate 50A or the thermally conductive substrate SOB may be caused to protrude from the module 10 in the width direction by increasing the size of the thermally conductive substrate 50A or the thermally conductive substrate 50B in the width direction larger than the size of the module 10 in the width direction. At this time, it is not absolutely necessary that the top portion of the thermally conductive substrate 50B or the like is caused to significantly protrude from the top portion of the module 10. That is, the height of the roughness of the thermally conductive substrate 50B or the like may be set according to the height of the roughness of the module 10.

In this configuration, the cooling effect of the cooling side of the module 10 is improved and a temperature difference in the thermoelectric conversion layer is increased in the same manner. Thus, the power generation amount can be improved.

In all of the above thermoelectric conversion modules of the present invention, the thermoelectric conversion layer and the metal layer are provided, the low stiffness portions are provided on the metal layer at equal intervals in the longitudinal direction, and the module is alternately bent in a mountain-folded manner and a valley-folded manner at the low stiffness portions to form a bellows-like shape.

In contrast, the thermoelectric conversion module according to a third aspect of the present invention has a configuration in which thermoelectric conversion layers are provided to be arranged on one surface of a long support and the respective thermoelectric conversion layers are electrically joined to each other in a side portion in a longitudinal direction. According to the thermoelectric conversion module of the present invention, it is possible to obtain a thermoelectric conversion module with a simple configuration by reducing the number of members.

Although the thermoelectric conversion module, the method of manufacturing the thermoelectric conversion module, and the thermally conductive substrate according to the present invention are described above, the present invention is not limited to the above-described examples and various improvements and modifications may of course be made without departing from the spirit of the present invention.

The present invention can be suitably used for a power generation device or the like.

### EXPLANATION OF REFERENCES

10, 60, 70, 72, 74, 76, 82: (thermoelectric conversion) module
12, 12B, 12C, 52, 52B: support
12A, 52A: laminate
12M, 52M: metal film
12AR: roll
12BR, 12CR, 52AR: support roll
12M: metal film
14p: p-type thermoelectric conversion layer
16n: n-type thermoelectric conversion layer
18: connection electrode
18a, 54a, 56a: low stiffness portion
20: etching device
24: film formation device
26a, 26b: gear
28: upper plate
30: lower plate
32: pressing member
34: contact portion
50A, 50B, 50C, 50D: thermally conductive substrate
54, 56: metal layer
62, 80, 86: laminate
78, 84: heat dissipation member
90: heat source
92: heat insulating material
94: thermally conductive member

What is claimed is:

1. A thermoelectric conversion module comprising:
a long insulating support having flexibility;
a plurality of metal layers which are formed on one surface of the support with intervals in a longitudinal direction of the support;
a plurality of thermoelectric conversion layers which are formed on the same surface of the support on which the metal layers are formed with intervals in the longitudinal direction of the support; and
a connection electrode which connects the thermoelectric conversion layers adjacent to each other in the longitudinal direction of the support,
wherein the metal layer has low stiffness portions having stiffness lower than that of other regions in parallel with a width direction of the support, an interval between the low stiffness portions is constant in the longitudinal direction of the support, and further, the module is alternately bent in a mountain-folded manner and a valley-folded manner at the low stiffness portions of the metal layer in the longitudinal direction.

2. The thermoelectric conversion module according to claim 1,
wherein the connection electrode functions as a metal layer.

3. The thermoelectric conversion module according to claim 1,
wherein the low stiffness portion is at least either one of one or more slits formed on the metal layer to be parallel with the width direction of the support or a broken line formed on the metal layer to be parallel with the width direction of the support.

4. The thermoelectric conversion module according to claim 1, further comprising:
a p-type thermoelectric conversion layer and an n-type thermoelectric conversion layer which are alternately formed in the longitudinal direction of the support as the thermoelectric conversion layers.

5. A thermoelectric conversion module comprising:
a module main body formed of the thermoelectric conversion module according to claim 1; and
a thermally conductive substrate including a long insulating support having flexibility, and a plurality of metal layers entirely or partially formed on one surface of the support or formed with intervals in a longitudinal direction of the support, the metal layer having low stiffness portions having stiffness lower than that of other regions in parallel with a width direction of the support, the substrate being bent in a mountain-folded manner or a valley-folded manner, or alternately bent in a mountain-folded manner and a valley-folded manner at the low stiffness portions of the metal layer in the longitudinal direction,
wherein the module main body and the thermally conductive substrate are laminated by directing the support of the thermally conductive substrate to a surface from which a connection electrode is exposed by bending of the module main body and fitting roughness of the module main body and roughness of the thermally conductive substrate to each other.

6. The thermoelectric conversion module according to claim 5,
wherein the thermally conductive substrate is laminated on both surfaces of the module main body by directing the support of the thermally conductive substrate to the module main body and fitting the roughness of the module main body and the roughness of the thermally conductive substrate to each other.

7. The thermoelectric conversion module according to claim 5,
wherein a distance between a top portion of a mountain fold portion of the thermally conductive substrate and a top portion of a mountain fold portion of the module main body is 0.5 to 5 times a height of the roughness of the module main body.

8. The thermoelectric conversion module according to claim 7,
wherein the thermally conductive substrate has roughness having different heights.

9. The thermoelectric conversion module according to claim 5,
wherein the thermally conductive substrate protrudes from the module main body in the width direction of the support.

10. The thermoelectric conversion module according to claim 5, further comprising:
a heat dissipation member which is bent in a mountain-folded manner or a valley-folded manner, or alternately bent in a mountain-folded manner and a valley-folded manner and is formed of a long thermally conductive plate-like material,
wherein the heat dissipation member is laminated on the thermally conductive substrate by fitting the roughness of the thermally conductive substrate and roughness the heat dissipation member to each other such that facing surfaces of top portions of mountain fold portions of the thermally conductive substrate and top portions of mountain fold portions of the heat dissipation member are separated from each other.

11. The thermoelectric conversion module according to claim 10,
wherein the heat dissipation member has low stiffness portions having stiffness lower than that of other regions in parallel with the width direction and is bent in a mountain-folded or a valley-folded manner, or alternately bent in a mountain-folded manner and a valley-folded manner at the low stiffness portions.

12. The thermoelectric conversion module according to claim 10,
wherein the heat dissipation member has roughness having different heights.

13. The thermoelectric conversion module according to claim 5, further comprising:
a heat dissipation member which is bent in a mountain-folded manner or a valley-folded manner, or alternately bent in a mountain-folded manner and a valley-folded manner, is formed of a long thermally conductive plate-like material, and is larger than the module main body in the width direction,
wherein the heat dissipation member is laminated on the thermally conductive substrate by fitting the roughness of the thermally conductive substrate and roughness of the heat dissipation member to each other such that the heat dissipation member protrudes from the module main body in the width direction of the support.

14. The thermoelectric conversion module according to claim 13,
wherein the heat dissipation member has low stiffness portions having stiffness lower than that of other regions in parallel with the width direction and is bent in a mountain-folded manner or a valley-folded manner, or alternately bent in a mountain-folded manner and a valley-folded manner at the low stiffness portions.

15. A method of manufacturing a thermoelectric conversion module comprising:
performing, while transporting a long insulating support having flexibility in a longitudinal direction, a conversion layer forming step of forming a plurality of thermoelectric conversion layers on one surface of the support with intervals in the longitudinal direction of the support;
an electrode forming step of forming a connection electrode, which connects thermoelectric conversion layers adjacent to each other in the longitudinal direction of the support, on the same surface of the support on which the thermoelectric conversion layer is formed;
a metal layer forming step of forming a plurality of metal layers on the same surface of the support on which the thermoelectric conversion layer is formed with intervals in the longitudinal direction of the support; and
a low stiffness portion forming step of forming low stiffness portions having stiffness lower than that of other regions on the metal layer to be parallel with a width direction of the support so as to have a constant interval in the longitudinal direction of the support; and
further performing a bending step of after performing the metal layer forming step, the conversion layer forming step, the low stiffness portion forming step, and the electrode forming step, while transporting the support in the longitudinal direction, alternately bending the support in a mountain-folded manner and a valley-folded manner at the low stiffness portions of the metal layer in the longitudinal direction.

16. The method of manufacturing a thermoelectric conversion module according to claim 15,
wherein the electrode forming step also functions as the metal layer forming step.

17. The method of manufacturing a thermoelectric conversion module according to claim 15,
wherein the support has a metal film formed on the entire one surface, and
the electrode forming step, the metal layer forming step, and the low stiffness portion forming step are simultaneously performed by removing the metal film.

18. The method of manufacturing a thermoelectric conversion module according to claim 15,
wherein the bending step is performed by allowing the support to pass between gears having a pitch narrower than the interval between the low stiffness portions and engaged with each other.

19. A thermally conductive substrate comprising:
a long insulating support having flexibility; and
a plurality of metal layers entirely or partially formed on one surface of the support, or formed with intervals in a longitudinal direction of the support,
wherein the metal layer has low stiffness portions having stiffness lower than that of other regions in parallel with a width direction of the support, and further, the substrate is bent in a mountain-folded manner or a valley-folded manner, or alternately bent in a mountain-folded manner and a valley-folded manner at the low stiffness portions of the metal layer in the longitudinal direction.
